(19) United States
(12) Patent Application Publication
(10) Pub. No.: US 2025/0377286 A1
(43) Pub. Date: Dec. 11, 2025

(54) METHOD AND SYSTEM FOR CORROSION PROTECTION

(71) Applicant: DEAKIN UNIVERSITY, Geelong, Victoria (AU)

(72) Inventors: Mike Yongjun TAN, Geelong (AU); Facundo Nahuel VARELA, Highton (AU)

(73) Assignee: DEAKIN UNIVERSITY, Geelong, Victoria (AU)

(21) Appl. No.: 18/872,131

(22) PCT Filed: Jun. 6, 2023
(86) PCT No.: PCT/AU2023/050492

§ 371 Date: Dec. 5, 2024

(30) Foreign Application Priority Data
Jun. 6, 2022 (AU) 2022901539

(51) Int. Cl. G01N 17/02; C23F 13/04; C23F 13/22; G01N 17/00; G01N 17/04

(52) U.S. Cl. CPC G01N 17/02; C23F 13/04; C23F 13/22; G01N 17/006; G01N 17/04; C23F 2213/31; C23F 2213/32

(57) ABSTRACT

A method of controlling corrosion in a metallic structure subjected to cathodic protection is disclosed. The method includes providing a probe that is capable of simulating at least one condition of the metallic structure and measuring at least one characteristic at the probe indicative of one or more states of the probe. At least one parameter of the cathodic protection applied to the metallic structure is controlled in response to the at least one measured characteristic. A control system for controlling a corrosion protection system and to a cathodic protection system applied to an apparatus for monitoring and controlling corrosion in a metallic structure.

### TECHNICAL FIELD

This disclosure relates to the field of corrosion protection of metallic structures using cathodic protection. More specifically, it relates to systems and methods for controlling such systems in order to control corrosion especially localised corrosion. The disclosure has particular application to cathodic protection systems for pipelines and is herein described in that context. However, it is to be appreciated that the disclosure is not limited to that use and the systems and methods disclosed may be used in relation to other metallic structures such as tanks, underwater structures and the like in soil, ocean and other aqueous media.

### BACKGROUND ART

Cathodic protection technique is widely used to protect metallic structures such as pipelines, storage tanks etc against corrosion. The technique involves impressing a cathodic current on to the metallic structure such that corrosion processes occurring in the metallic structure can be suppressed. The impressed current levels are typically static and can be adjusted if desired based on changes that occur to the corrosion conditions in the metallic structure. One way of monitoring for changes in the corrosion conditions is through potential measurements. In this regard, the potential of the metallic structure can be monitored in relation to a reference electrode that has a defined potential. A buried steel pipeline can be considered to be effectively protected by cathodic protection if the potential level of −850 mV vs. copper/copper sulphate/sat. reference electrode (CSE) is applied on the metallic structure. In some cases, the output from the cathodic protection system can be varied when there is a presumed change in environmental and corrosion conditions.

However, the potential is not directly related to the occurrence of localised forms of corrosion. For example, pipelines used for transport of various liquids and gases often come with a coating that protects the pipeline from the elements of weather.

Typically, the coating comprises an epoxy-based material. However, disbondment of the coating may occur under certain conditions (e.g. overprotection by impressing high currents can result in coating disbondment due to the generation of excessively high pH and hydrogen gas). Such a disbondment leads to the creation of an air-gap between the coating and the metallic structure. The air gap can act to prevent cathodic currents from reaching the region of the defect causing a ‘shielding’ of that portion of the pipeline from the cathodic protection system. Corrosion can then be initiated in this shielded portion of the pipeline in the presence of moisture and corrosive species. Such a localised corrosion phenomenon, also known as corrosion under disbonded coatings (CUD), can result in failure of the pipeline if left unaddressed.

Furthermore, monitoring systems based on potential monitoring also have issues associated with IR-drops, leading to significant inaccuracy of corrosion potential measurement. These IR-drops could be caused by various electrical currents in the environment including stray currents which are unpredictable and change dynamically.

Because potential is not directly related to the occurrence of localised forms of corrosion such as CUD or stray current corrosion, there are shortcomings in using it as an indicator for adjusting cathodic protection output levels. Incorrect adjustment of cathodic protection output can lead to under protection and overprotection. Both under protection and overprotection can have undesirable consequences.

Accordingly, there is a need for a more reliable indicator for adjusting cathodic protection output levels. There is also a need for improved methods of controlling localised corrosion in metallic structures.

It is to be understood that, if any prior art is referred to herein, such reference does not constitute an admission that the prior art forms a part of the common general knowledge in the art, in Australia or any other country.

### SUMMARY

In a first aspect, disclosed is a method of controlling corrosion of a metallic structure subjected to cathodic protection. The method includes providing a probe that is capable of simulating at least one corrosion condition of the metallic structure; measuring at least one characteristic at the probe indicative of one or more states of the probe; and controlling at least one parameter of the cathodic protection applied to the metallic structure in response to the at least one measured characteristic.

In at least some forms, the method provides a direct way of monitoring conditions that may be occurring on the metallic structure by using a probe as a proxy for those conditions. This allows for implementation of a response in cathodic protection to changes in conditions occurring at the probe which are simulating conditions at the metallic structure. The adjusting of cathodic protection output is based on at least one measured characteristic (or indicators) monitored using the probe. The method is particularly suited to control localised corrosion of the metallic structure.

In some embodiments, the method comprises associating the probe and the metallic structure with one another so that they are maintained at the same electrical potential whereby corrosion and cathodic protection at the metallic structure also occurs at the probe.

In some embodiments, the probe is electrically coupled to the metallic structure. This allows changes implemented to the probe to be implemented at the pipeline.

In some embodiments, one of the states of the probe is the rate of corrosion at the probe and the measured characteristic is anodic current at the probe.

In some embodiments, the probe is subject to cathodic protection and at least one of the states of the probe is a state of overprotection of the probe by the cathodic protection.

In some embodiments, the measured characteristic is cathodic current at the probe.

In some embodiments, the method comprises reducing the cathodic protection applied to the metallic structure when the measured characteristic indicative of a state of overprotection at the probe is outside a predetermined criteria.

In some embodiments, at least one of the states of the probe is a passivated state.

In some embodiments, the measured characteristic is both anodic and cathodic currents at the probe.

In some embodiments, the method comprises reducing and/or removing the cathodic protection applied to the metallic structure when the measured characteristic indicative of a passivated state at the probe is within a predetermined criteria.

In some forms, a passivated state is indicated by significant decrease in corrosion rates.

In some embodiments, the at least one characteristic is measured at the probe at regular intervals.

In some embodiments, the environmental conditions of the probe are correlated with the environmental conditions of the metallic structure.

In some embodiments, the probe is exposed to the same, or substantially the same, environmental conditions as the metallic structure.

In some embodiments, the at least one condition is a localised condition of the metallic structure.

In some embodiments, the probe is configured to simulate a defect of the metallic structure. In some embodiments, the defect is a disbonded coating.

In some embodiments, the metallic structure is coated and the localised condition is corrosion under disbonded coating.

In some embodiments, the localised condition is stray currents interacting with the metallic structure.

In some embodiments, the probe comprises an array of electrodes and the measuring of the at least one characteristic at the probe comprises measuring the at least one characteristic at a plurality of the electrodes to form a distribution map of the measured characteristic across the array of electrodes. This allows for spatial and temporal resolution of the processes occurring on the surface of the pipeline.

In some embodiments, the at least one parameter is controlled in response to the distribution map of the at least one measured characteristic.

In some embodiments, the metallic structure is a pipeline buried in soil.

In some embodiments, the probe is configured to simulate the at least one corrosion condition of the metallic structure located in a non-homogenous environment.

In a further aspect, a method of controlling at least one parameter of a corrosion protection system is disclosed. The method comprises providing a probe that is capable of simulating at least one corrosion condition of a metallic structure; measuring at least one characteristic at the probe indicative of one or more states of the probe; and controlling at least one parameter of the corrosion protection system in response to the at least one measured characteristic.

In some forms, the above method utilises features otherwise disclosed in respect of any form of the earlier aspects disclosed above.

In a further aspect, disclosed is a control system for controlling a corrosion protection system for a metallic structure; comprising a controller for controlling at least one parameter of the corrosion protection system; and a probe capable of simulating at least one condition of the metallic structure; wherein the controller is adapted to receive data from the probe, the data being indicative of one or more states of the probe, and determine a control signal for controlling the at least one parameter of the corrosion protection system on the basis of the data from the probe.

In some embodiments, the controller comprises a processing module configured to determine the control signal.

In some embodiments, the control signal is provided to the corrosion protection system over a wireless network.

In some embodiments, the control system is adapted to receive control input which comprises one or more control parameters.

In some embodiments, the one or more control parameters comprise one or more of protective current threshold, overprotection time allowance.

In some embodiments, one or more of the one or more control parameters are updatable over a wireless connection.

In some embodiments, the processing module is located remote to the probe and the metallic structure.

In some embodiments, the probe and the controller are configured to implement the methods as described hereinabove.

In a further aspect, disclosed herein is a corrosion protection system for protecting a metallic structure, the corrosion protection system being coupled with a control system as described hereinabove, wherein the metallic structure is electrically connected to the probe of the control system.

In yet a further aspect, there is disclosed a metallic structure being protected against corrosion by a corrosion protection system according to any form above.

In some embodiments of the method, control system, corrosion protection system, or metallic structure disclosed above, a plurality of probes are provided to simulate multiple corrosion conditions of the metallic structure and/or conditions of the metallic structure in non heterogeneous environments.

In some forms, the metallic structure is a pipeline.

### BRIEF DESCRIPTION OF THE DRAWINGS

Embodiments will now be described by way of example only, with reference to the accompanying drawings in which:

FIG. 1 shows a schematic of the system according to an embodiment of the disclosure;

FIG. 2 shows an enlarged view of a section of FIG. 1;

FIG. 3A shows a plan view of the probe used in the system of FIG. 1;

FIG. 3B shows an end view of the probe of FIG. 3A;

FIGS. 4A-4D is a flowchart of the controller logic employed in the system of FIG. 1;

FIG. 5 shows a control arrangement for use in the system of FIG. 1;

FIG. 6 shows a variation of the control arrangement of FIG. 5;

FIG. 7 shows a schematic of a setup of Example 1;

FIG. 8 shows the evolution of potential and current versus time of the setup of FIG. 7 in response to anodic perturbations;

FIGS. 9A-9C shows the evolution of current density across the probe of the setup of FIG. 7 in response to anodic perturbations;

FIGS. 10A & 10B illustrate the response of the setup of FIG. 7 under dynamic conditions;

FIG. 11 shows a schematic of a setup of Example 2;

FIG. 12 shows finite element simulation results for the potential distribution of a set up FIG. 11 in infinite media;

FIG. 13 shows finite element simulation results for the potential distribution of a set up FIG. 11 in an isolated box;

FIG. 14 shows simulation results for the potential distribution of a set up of FIG. 11 in a box, using outer electrodes;

FIG. 15 shows the difference in potentials between two electrodes of the setup of FIG. 11 subjected to varying stray currents;

FIG. 16 shows the distribution of current across various electrodes of a probe of the setup of FIG. 11 when subjected to varying stray currents;

FIGS. 17A-17D show the current density map of the probe at different stray currents when using conventional autopotential control in Example 3;

FIGS. 18A-18D show the current density maps of the probe at different stray currents when using closed loop control in Example 3;

FIG. 19A shows a schematic of the system of Example 4;

FIGS. 19B & 19C show the evolution of currents across a probe used in the setup of FIG. 19A before and after a CP malfunction event:

FIGS. 19D & 19E show the variation of potential, output current and rainfall from the CP system before and after a CP malfunction event;

FIG. 20 shows the correlation between corrosion and rainfall of Example 5; and

FIGS. 21A & 21B show the evolution of corrosion rates on a probe during testing in a marine environment of Example 6.

### DETAILED DESCRIPTION

In the following detailed description, reference is made to accompanying drawings which form a part of the detailed description. The illustrative embodiments described in the detailed description, depicted in the drawings and defined in the claims, are not intended to be limiting. Other embodiments may be utilised, and other changes may be made without departing from the spirit or scope of the subject matter presented. It will be readily understood that the aspects of the present disclosure, as generally described herein and illustrated in the drawings can be arranged, substituted, combined, separated and designed in a wide variety of different configurations, all of which are contemplated in this disclosure.

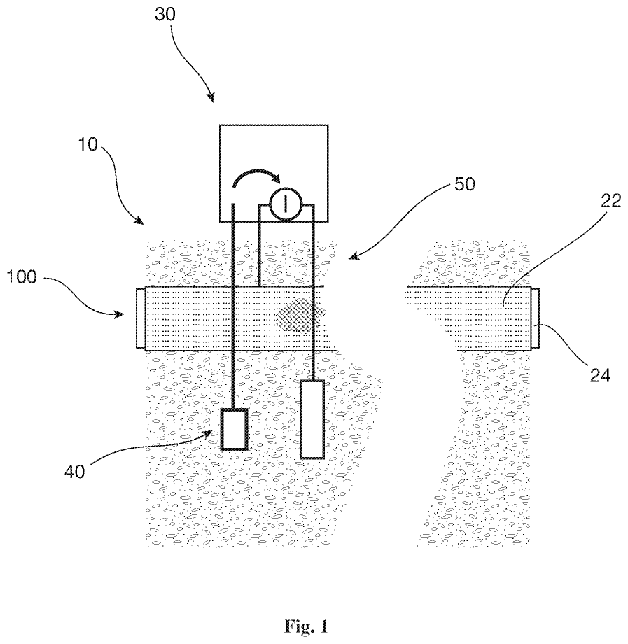

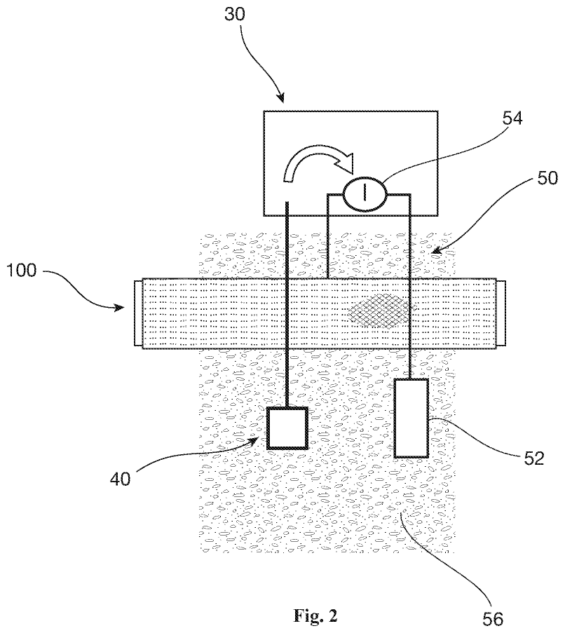

FIGS. 1 and 2 are schematic illustrations of a cathodic protection system (CPS) 50 connected to a metallic structure, which in the form shown is a buried gas pipeline 100. A control system 10 including a controller 30 coupled to a probe 40 acts as an interface between the CPS 50 and the pipeline 100 that enables monitoring and controlling of the cathodic protection applied by the CPS 50 to the pipeline 100.

The control system 10 is arranged to operate by the probe 40 being able to simulate at least one condition of, or occurring at, the pipeline 100 and to cause the CPS 50 to take an appropriate corrective action at the pipeline. In this manner, a corrosion condition which may have begun on the pipeline 20 may be addressed quickly. Thus, the disclosed method obviates, or at least minimises, the requirement for expensive equipment needed to confirm that condition and pinpoint the location for that condition before tackling that condition.

The presence of a condition is ascertained by detecting and measuring a characteristic at the probe 40 and analysing it.

The CPS 50 is an impressed current cathodic protection system and comprises an anode 52, a rectifier 54 and a cathode. The objective of the cathodic protection system is to convert the structure to be protected into the cathode and thereby prevent corrosion from occurring on the structure. The oxidation reactions are forced to occur at the anode 52 instead of the cathode where reduction reactions occur. Thus, in the present case, the structure to be protected—the gas pipeline 100 will act as the cathode. The anode 52 is generally made out of a material that may be inert/replaceable. The rectifier 54 is connected between the anode 52 and the pipeline 100 and is thus able to drive the current from the anode to the cathode. The anode 52 and the pipeline (cathode) 100 are buried in the soil 56 which completes the electrical circuit between the cathode and the anode 52. The rectifier 54 may be located above the ground and near to or remotely from the pipeline 100. The anode 52 and cathode must be in proximity to each other to minimise losses due to resistance.

In some embodiments, the probe and the metallic structure are associated with one another so that they are maintained at the same electrical potential. Thus, the cathodic protection that is applied to the pipeline 100 is also applied at the probe 40. This facilitates the probe 40 to simulate the conditions at the pipeline 100. Similarly, in the illustrated embodiment, the probe 40 is electrically coupled to the pipeline 100 through the controller 30. Accordingly, changes that are enforced at the probe 40 are automatically enforced at the pipeline 100 For example, if output current from the rectifier 54 is reduced to the pipeline 100, it is also reduced to the probe 40.

The controller 30, which controls the CPS 50, is connected to both the CPS 50 and the probe 40 and ensures that effective cathodic protection is applied and maintained at the pipeline 100. The controller functions to gather data from both the CPS 50 and the probe 40, analyses the data and follows a preprogramed algorithm to ascertain the effectiveness of the CPS 50 and adjusts the output of the rectifier 54 of the CPS 50 appropriately as required. For example, if the controller determines that the CPS 50 is not providing sufficient protection, it takes action and instructs the CPS 50 to adjust the output from the rectifier 54 so as to increase the level of protection. In the illustrated form, the controller 30 is able to gather the anodic corrosion current density values from the probe 40 and then calculate the corrosion rates. If it determines that the corrosion rates at the probe are above a threshold, it instructs the CPS 50 to increase current output from the rectifier 54 by a level that will reduce the anodic current density accordingly.

In the illustrated form, the controller comprises a proportional controller. In other forms, the controller could include a proportional integral derivative controller.

In the illustrated form, the controller 30 (and the probe 40) is located near the rectifier 54 of the CPS 50. However, in other forms, the controller 30 and probe 40 may be located remotely from the rectifier 54. Wireless communication methods such as RF Radio, GSM, Satellite and LoRa could be used to link the rectifier 54 with the controller 30 and probe 40. In other forms, the controller 30 can be configured to gather data from a network of remote probes 40. This controller 30 can again remotely or locally interface with the rectifier 54.

The probe 40 may be in the form of a wire beam electrode (WBE). The WBE probe 40 may perform multiple functions as will be described in greater detail below. In the form shown, the WBE probe 40 is fabricated from the same material as that of the pipeline 100 being protected. This simplifies the control function of the system as it allows a direct correlation between the probe and the pipeline. However, it is to be appreciated that the probe may be made from a different material to the pipeline. In such a case a correlation factor is utilised to correlate the corrosion at the probe against the expected corrosion at the pipeline.

The array of electrodes in the WBE probe 40 is disposed in a matrix of polymeric material such as epoxy. Each electrode in a row/column is separated from the adjacent electrode in a row/column through an epoxy containing resin that acts as an insulator and is impermeable to liquids. In this manner, the WBE offers the ability to obtain spatial and temporal resolution of the corrosion processes occurring on the metal surface. Such a configuration allows a user to obtain maps of various electrodes over a period of time. Valuable information regarding the corrosion processes can be obtained from analysing these maps.

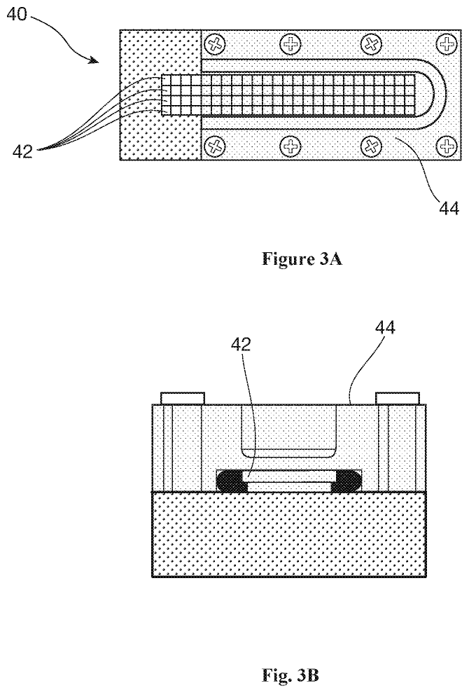

In the illustrated form, the WBE probe 40 comprises a plurality of electrodes 42 disposed along its length and breadth. In the embodiment shown, the probe 40 comprises 100 electrodes in a 25×4 array (see FIG. 3A). Each electrode is a square shaped of 2.24 mm×2.24 mm, spaced 0.3 mm apart from the adjacent electrode. It will be apparent to a person skilled in the art that other shapes and sizes of electrodes can be employed. For example, the array could also comprise 1.6 mm diameter wires in a 10×10 array of 18.5 mm×18.5 mm.

The probe also comprises electronics (not shown) connected to the electrodes 42 of the WBE 40. The electronics allow detection and measurement of various parameters at the electrode. For example, anodic currents or potentials can be measured at each electrode of the array thus providing an indication of corrosion processes occurring at each electrode and the corrosion rates of such processes. Similarly, cathodic currents can also be measured at each electrode of the array to provide an indication of overprotection at the electrode.

The array of electrodes offers the ability to provide a spatial and temporal resolution of the processes occurring in the probe under ambient environmental conditions. The occurrence of a corrosion process is determined by the detection of an anodic current at the electrode. By measuring the amount of anodic current detected at each electrode, the extent of corrosion can be quantified at that electrode. Thus, anodic current density (anodic current/surface area of electrode) is a direct measure of the corrosion rate at that electrode. Since the monitoring of currents can be performed in a continuous manner, the data provides a useful, real-time measure of the corrosion rates at each electrode.

Similarly, the probe 40 is also configured to measure cathodic currents and their distribution at the electrode. This is extremely useful in ensuring that the cathodic protection system does not overprotect the structure.

By analysing the corrosion rates over a period of time, the stability of the CPS 50 can be ascertained in a direct manner. Further, by obtaining a map of corrosion rates, it is possible to determine the extent of corrosion occurring. For example, it can be ascertained whether all the electrodes under the array are being corroded or only a portion of the electrodes are subject to corrosion. Such measurements provide useful insights into the nature of processes occurring (described in more detail below).

The location of the probe 40 in the control system 10 is designed such that the probe is able to replicate the surface conditions of the pipeline so that similar corrosion processes are expected to occur on both the probe and the pipeline. For example, in the form shown, the probe is not be placed too far from the pipeline such that the environmental conditions are entirely different from that of the pipeline. Similarly, the probe is placed at a similar depth as the pipeline. Environmental conditions would include the following factors: soil humidity, particle size, oxygen contents, soil pH, electrical conductivity and other factors affecting corrosion and cathodic current distribution. In the embodiment disclosed, the probe is located at a distance of about 50 cm to 1 m from the pipeline. However, the person skilled in the art will realise that the key consideration in placement of probe is the need to provide the same surface condition to the probe as the pipeline. Typically, the best time to install the probe is when the pipeline is being constructed.

The number of probes to be utilised can be chosen depending upon the length of pipeline to be protected and the environmental conditions encountered. For example, a pipeline that runs for long distances and encounters a variety of environmental conditions along its length may require multiple probes placed along its length to properly replicate the local environmental conditions being encountered by the pipeline. On the other hand, a pipeline that does not run for long distances and does not encounter a variation in the environmental conditions may be monitored by a single probe.

The probe 40 and controller 30 may be configured to allow control of the CPS 50 under different conditions of the metallic structure (i.e. pipeline 100). For example, pipelines that are exposed to ambient environment can encounter a wide variation in conditions. It is well known that ambient environment can significantly affect corrosion behaviour of a given metal. Accordingly, one of the functions of the WBE probe 40 may be to provide an indication of the nature and extent of corrosion that may occur in the ambient environment in which the pipeline is located. The WBE probe 40 is able to accomplish this by being located in an environment that is the same as that of the pipeline 100. For example, when it rains, the moisture content of the soil around the pipeline can be increased significantly. The WBE probe 40, being also subjected to the increase moisture content, will be able to provide an indication of how the material of the pipeline corrodes in conditions of high moisture/humidity content of the soil. Similarly, on very hot days, the moisture in the soil can significantly dry up leading to very low moisture contents. Thus, the WBE probe 40 may be able to provide an indication of the corrosion behaviour of the material of the pipeline in low moisture/humidity content environment.

In another scenario, on a given day, soil conditions along the pipeline may vary significantly (especially in pipelines that run for long distances). It may well be that one part of the pipeline 20 located in a first area is encountering wet conditions due to rain falling in that area while another part of the pipeline 100 that is located in a second area far away (e.g. 40-50 kms away) from the first area is encountering sunny weather and dry conditions. Accordingly, the pipeline 100 which is made from the same/similar material in both areas, would encounter different ambient conditions and thus corrode at different rates. By placing WBE probes 40 at different sections of the pipeline 100, it would be possible to monitor the real time corrosion processes occurring in any given section of the pipeline on that given day.

Similarly, seasonal changes and changes in patterns of rainfall, changes in weather from hot to cold etc. can cause significant differences in corrosion (due to differences in oxygen penetration associated with rainfall and dryness). For example, this may mean that corrosion is active only during certain periods of a year. The probe WBE 40 has the capability to detect such changes. By communicating data on these changes to the controller 30, the CPS 50 can adjust the CP as required to counter any increase in corrosion during these active corrosion periods. Such detection allows adjustment of CP levels during these periods. For example, the existing level of CP may be insufficient to counter corrosion processes occurring in the presence of very heavy rainfall. Detection of increased corrosion would allow the CP to be adjusted by the CPS 50 to a higher level to counter this increased corrosion.

The WBE probe 40 is also able to provide an indication of different states of the pipeline. This may include a state of overprotection of the pipeline by the cathodic protection system 50. Overprotection is a condition in which the cathodic protection current density is too high (or in other words, the protection potential is too low), leading to unwanted chemical changes at the coating/metal interface. Such unwanted chemical changes can lead to unwanted damages to coatings and steels. For example, the high cathodic currents can cause oxygen reduction and breakdown of moisture/water, leading to excessive generation of hydroxyl ions and hydrogen evolution may cause coating disbondment. Hydrogen evolution can also result in issues such as hydrogen embrittlement, coating disbondment etc. Accordingly, by monitoring for the occurrence of cathodic currents that are more than a threshold, the WBE probe 40 is able to provide indication of overprotection.

The WBE probe 40 may also provide an indication of whether there are potential faults with the CP protection system. For example, if for some reason, the CP protection system has shutdown/not working, then corrosion processes will initiated at the WBE probe 40 (since the cathodic protection is no longer working). Since the WBE probe is being constantly monitored, it can be configured to trigger an alert in case the anodic currents increase. The controller can then be configured to respond to such events appropriately (e.g. by performing troubleshooting/informing the operator of the alert etc).

In some embodiments, the control system 30 is configured to monitor and respond to a passivated state of the pipeline 100. A passivated state is a state in which anodic currents decrease to a very small value close to zero or within acceptable limits. It is formed when a protective layer exists over the pipeline that prevents corrosion reactions from occurring. Since the pipeline is inherently protected in a passivated state, there is no need to continue supplying high level current from the cathodic protection system.

The WBE probe 40 may also be configured to simulate conditions of the metallic structure. Such conditions may be defects such as a disbonded coating on the pipeline. In this manner, the effect of corrosion processes in the presence of the defect can be estimated accurately. For example, pipelines are often coated to protect them from the ambient environment. Coatings may include for example epoxy based coatings and polyurethane coatings. Such a coating is typically bonded to the outer surface of the pipeline. However, under certain circumstances, the coating may become detached from the outer surface leading to the formation of a gap between the pipeline and coating. Such a gap can also be shielded by the disbonded coating resulting in loss of corrosion protection to the region of the pipeline beneath the disbonded coating. Moisture and corrosive media can be trapped in this gap leading to acceleration of corrosion processes occurring in these areas of a pipeline. While possible, it is very difficult and expensive to detect the onset and progress of such disbonding and corrosion occurring under the coating.

The WBE probe 40 can also be configured to simulate other defects such as a dissimilar metal joint, weld joints by using electrode elements of different materials and microstructural features in different designs.

As described above, in some embodiments, the probe 40 can be configured to simulate a localised condition of the pipeline 100. Such conditions, may not be present on the pipeline initially but develop over the course of time. The probe 40 can be configured to simulate a defect of the pipeline 100. Thus, the control system 10 enables information to be obtained on the conditions of the pipeline 100 having defects. In some embodiments, the defect is a disbonded coating which can occur on coated pipelines with time due to a variety of reasons. The air gap created beneath the disbonded coating can give rise to corrosion. Thus, the localised condition can be corrosion that occurs under the disbonded coating. The system 10 may be configured to monitor and handle such a corrosion condition as well.

In some embodiments, the localised condition is caused by stray currents interacting with the pipeline 100. This is especially evident in case of pipelines laid near facilities such as a railway tracks or electricity transmission lines. Inevitably, there are leakages associated with such facilities and the leaked currents can interact with the pipeline causing disturbances to the cathodic protection system. The control system 10 is able to identify such stray currents as they cause dynamic change of anodic currents over the probe 40 and cause change of potential. Thus, the level of CP level changes dynamically.

In the form of the control system 10 as illustrated, the probe 40 is connected to the controller 30. The controller 30 is further coupled to the CPS 50 that provides the impressed current/potential needed to protect the pipeline 100 from corrosion. The controller 30, the probe 40 and the cathodic protection system 50 together form a closed loop system that monitors and controls the cathodic protection system 50 applied to pipeline 100.

In some embodiments, the probe 40 is configured to simulate a corrosion condition on the pipeline 100. The controller 30 is configured to analyse the anodic current density to calculate a corrosion rate. Thresholds for corrosion rates are known in the industry (e.g. <0.1 mm/year is a commonly used benchmark for acceptable corrosion rates in the industry). Such thresholds can be used to set a predetermined criteria that is used by the controller 30. The controller 30 may make a comparison between the calculated corrosion rate and the benchmarked corrosion rate to make a decision on adjusting the output of the CPS 50. If the controller 30 determines that the calculated rate of corrosion is greater than the benchmark, it can increase the cathodic protection by increasing output current from rectifier 54 in order to counter the measured anodic currents and the corrosion process. This may also be achieved by detecting pH values on the probe surface, for instance, if pH drops to less than 8, cathodic protection output current would need to be increased in order to increase the pH and maintain passivity of the steel surface (usually pH to above 9).

In one form, the output current to be applied to the pipeline is calculated by the controller using the constant of the proportional controller Kp. This constant is dependent on the surrounding soil, the state of coating degradation and can be ascertained by trial and error. For example, in case of a corrosion condition where anodic currents are detected, the controller 30 is required to apply a cathodic current to the pipeline. This current is calculated as the magnitude of the maximum anodic current (to counter the most severe corrosion rates) and Kp to calculate the current to be output from the rectifier 54.

In some embodiments, the probe 40 in configured to monitor and control for an overprotection condition on the pipeline 100. In this case, the measured characteristic is cathodic current. The controller 30 is configured to analyse the cathodic current density. Again thresholds for overprotection can be set. For example, it is known that cathodic current densities due to an oxygen reduction reaction (a desirable reaction that causes passivation and stable protection from corrosion) and a hydrogen evolution reaction (an undesirable reaction that indicates a state of overprotection) are different. It is thus possible to use these values to set predetermined criteria. The controller 30 can then compare the measured cathodic current density with these values to determine if the probe 40 is in a state of overprotection. If the controller 30 determines that the calculated cathodic current density is outside the predetermined criteria, it can reduce the cathodic protection by decreasing output current from the rectifier 54.

As discussed above for the case of a corrosion condition, the output current calculation may be accomplished using the constant of proportionality Kp. The constant of the proportional controller used in this instance Kpc is different from the constant of the proportional controller used to set the cathodic current for combating the corrosion process.

In some embodiments, the probe 40 is configured to monitor and respond to a passivated state of the pipeline 100. The presence of a passivated state can again be monitored by monitoring the anodic and cathodic current densities at the probe 40 when the CPS 50 is in a switched off condition. As above, predetermined criteria can be provided to characterize this passivated state (e.g. anodic and cathodic current densities within certain limits). Accordingly, if the controller 30 determines that the current densities are within the predetermined criteria, it can reduce or stop the output current from the rectifier 54. The controller may have preset conditions at which it performs this passivation measurement. For example, the controller periodically interrupts the output current from the rectifier 54 to identify if sustainable anodic currents are present. Presence of sustainable anodic currents outside the predetermined criteria indicates that the probe 40 is not in a passivated state. On the other hand, anodic currents within the predetermined criteria would indicate a passivated state.

In some embodiments, the measurement of the at least one characteristic at the probe is done at regular intervals. For example, the anodic current densities at the probe 40 are monitored every 10-60 seconds. Similarly, the cathodic current densities at the probe 40 are monitored every 10-60 seconds. This allows for a continuous, real-time monitoring and tracking of the probe 40 and pipeline 100. Slower data logging may be acceptable for less dynamically changing pipeline conditions.

In the illustrated embodiment, the probe 40 comprises an array of electrodes 42 as described above. Thus, the control system 10 may be configured to measure the at least one characteristic at the probe at a plurality of the electrodes 42 so as to form a distribution map of the measured characteristic across the array of electrodes. As previously described, this offers the ability to perform spatial and temporal analysis of the conditions thereby extracting further useful information and allowing the probe 40 to more closely simulate the conditions on the pipeline 100. The controller 30 then analyses the distribution map to make decisions to adjust the current output from the rectifier 54.

In the illustrated embodiment, the controller 30 can be configured to adjust the output current from the rectifier 54 until all the electrodes in the array present a net cathodic current. Alternatively, the controller 30 can be configured to analyse whether the magnitude and number of anodic currents at different electrodes present an accumulated metal loss rate that is acceptable (e.g. <0.1 mm/year).

Similarly, if the controller 30 detects cathodic currents near the crevice opening (in the case where the probe 40 is simulating disbonded coating described below), it can be configured to determine if those current densities are larger than those produced by oxygen reduction in that environment and accordingly adjust the output CP current from the rectifier 54.

The use of an array also allows the controller 30 to perform additional measurements. For example, the controller can interrupt the output current from the rectifier 54 to determine if CP shielding is occurring using the current distribution maps. If there is no difference in the current distribution maps before and after interruption of CP, it would indicate that CP shielding is occurring. To further determine the cause of shielding, the controller 30 can increase the output current to the maximum permissible value from the rectifier 54. This would overcome any IR-drops that are causing the shielding and reflect in the cathodic gradient extending deeper into the array (i.e. more electrodes would now start presenting cathodic currents). On the other hand, even after increasing the output current from the rectifier 54 to the pipeline 100, there is no difference observed in the current distribution maps, then it can indicate a lack of continuity in the electrolyte.

In one form, the measurement of the at least one characteristic at the array of electrodes can be accomplished using the following set up. An automatic switcher (CPE systems) is programmed to connect one electrode of the array (the one corresponding to the measurement) to a second working electrode (WE2) and systematically alternate it every 1 s to scan the whole array in 100 s. The other 99 electrodes remain connected to a first working electrode (WE1). A zero resistance ammeter (ZRA) is interposed between WE1 and WE2 to measure the local current throughout WE2. The current signals obtained by both ZRAs were postprocessed with an ad-hoc MatLab 2015b script.

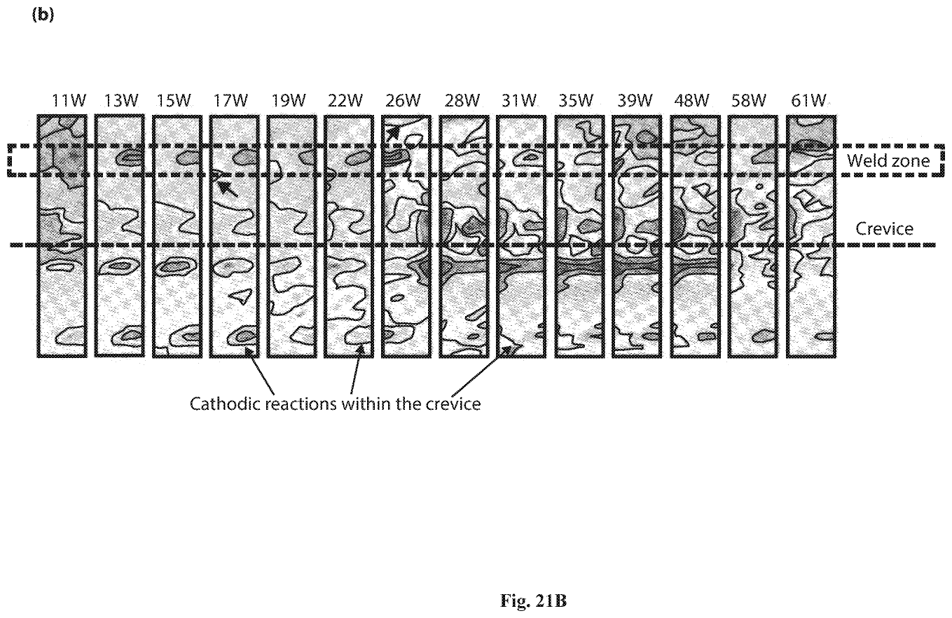

Turning to a specific embodiment as disclosed in FIGS. 3A and 3B, the WBE probe 40 is designed to simulate a disbonded coating. In this form, the WBE probe 40 may comprise a cover 44 made of clear plastic such as PMMA that is located so as to partially cover the electrodes of the array. In the embodiment shown in FIGS. 3A and 3B, 21 of the 25 rows of electrodes is located beneath the plastic cover 44 while the remaining 4 rows of electrodes is located outside of the plastic cover 44. The acrylic cover is configured such that there is a gap between the top surface of the plurality of electrodes 42 and the bottom surface of the cover facing the top surface of the electrodes. The gap is further surrounded by a rubber washer that seals off the electrode array from all sides except one side along the length of the array. In this manner, the configuration of the acrylic cover, air gap and the array of electrodes simulates a disbonded coating defect on the pipeline 100.

The gap between the acrylic cover and the electrode surface may be varied to simulate coating disbondment defects with different geometries. For example, in some embodiments, the gap may be 1 mm. This is recognized as the most corrosion prone size. In other embodiments, the gap may be 0.05 mm or 2 mm.

In the present embodiment, where the probe 40 is designed to stimulate disbonded coating on the pipeline 100, when an anodic current is detected at the electrodes 42 located outside the plastic cover 44, it is an indication that corrosion is occurring under the ambient conditions for the material. This provides the first indication of corrosion. Accordingly, the controller can take action to counter the corrosion processes.

Similarly, cathodic currents indicate an overprotection condition at the WBE probe. By obtaining an indication of the state of the probe 40, it is possible to obtain proxy of the state of the pipeline that is associated with the probe 40 (i.e. the section of the pipeline which the probe is attempting to simulate). The use of a WPE to assess the impact of overprotection on coating disbondment is the subject of the following reference, the content of which is herein described by cross reference {F. Mahdavi, M. Forsyth, M. Y. Tan, Understanding the effects of applied cathodic protection potential and environmental conditions on the rate of cathodic disbondment of coatings by means of local electrochemical measurements on a multi-electrode array, Prog. Org. Coat., 103 (2017) 83-92}.

Based on the measured characteristic, the method allows for controlling at least one parameter of the cathodic protection applied to the pipeline 100 by the CPS 50. For example, the output current or output potential of the cathodic protection can be one such parameter that is adjusted in response to the measured anodic/cathodic current. The method also allows for controlling the cathodic protection based on the results from the monitoring stage. Thus, when it is detected that corrosion or overprotection is occurring by measuring the anodic or cathodic current densities, steps can be taken at an early stage to combat those conditions and avoid further damage to the pipeline.

The response of the controller may be established based on relationships between cathodic protection output level and corrosion activities, especially localised corrosion such as corrosion under disbonded coatings. Such relationships have been the subject of previous work by the inventors and can be found in the following references, the contents of which are incorporated by cross reference {M. Y. Tan, Y. Huo and F. Varela, Field and laboratory assessment of electrochemical probes for visualizing localized corrosion under buried pipeline conditions, Journal of Pipeline Science and Engineering 1 (2021) 88-99; F. Varela, M. Tan, M. Forsyth, Understanding the effectiveness of cathodic protection under disbonded coatings, Electrochim. Acta, 186 (2015): p. 377-390; K. Wang, F B Varela and MY Tan, Probing dynamic and localised corrosion processes on buried steel under coating disbondments of various geometries, Corrosion science, 150:151-160 15 Apr. 2019}

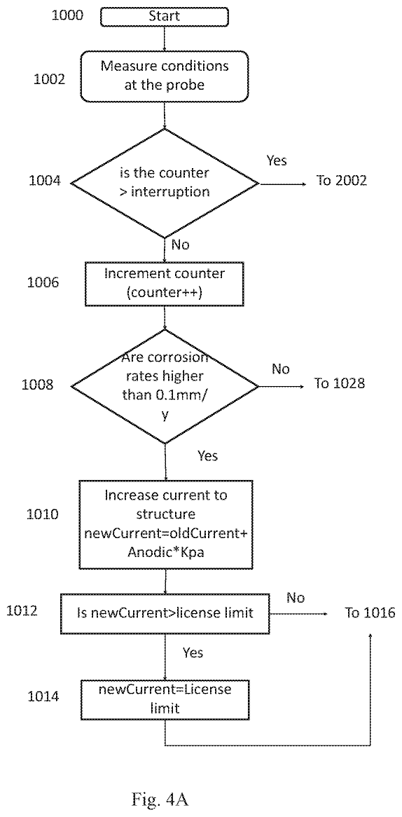

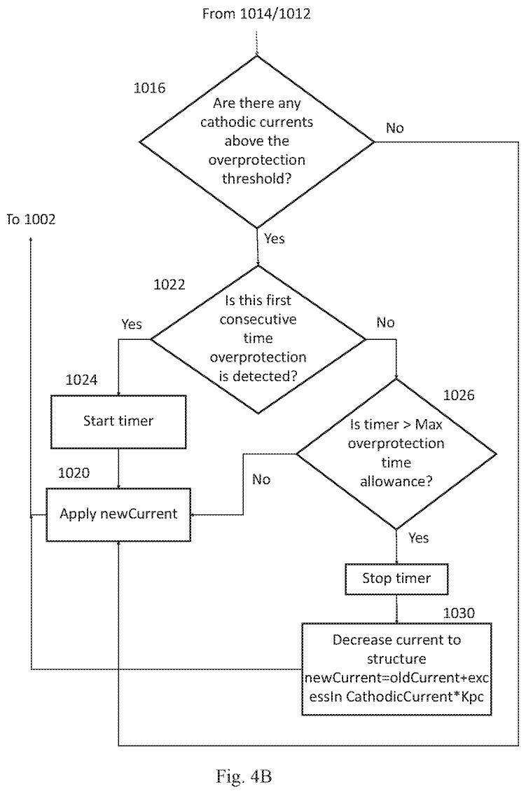

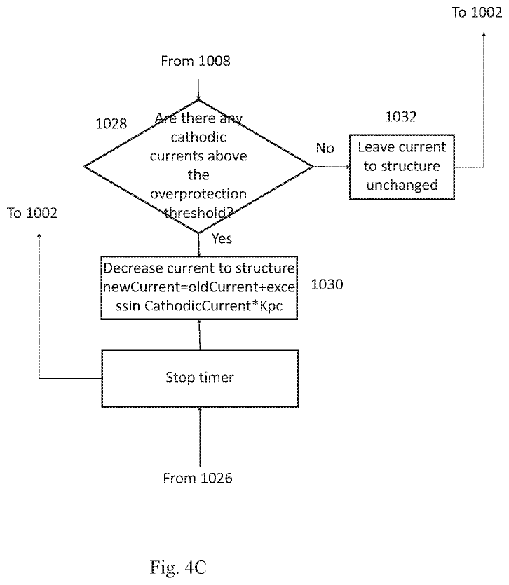

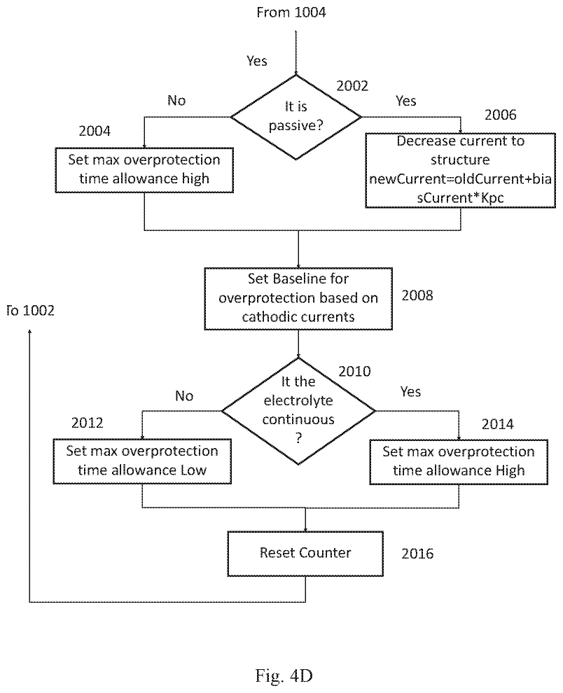

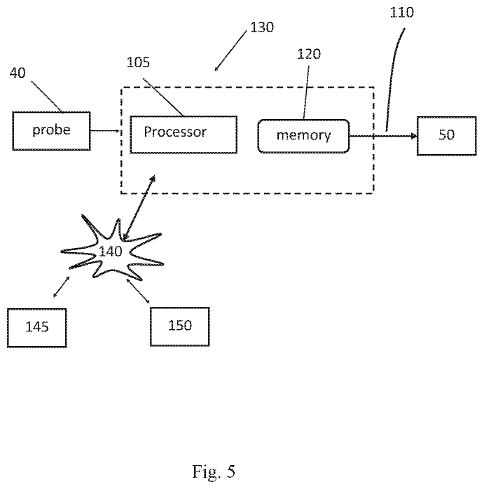

An embodiment of the control methodology that the control system 10 may use with the WBE probe 40 of FIGS. 3A and 3B is described with reference to the flow diagram of the logic in the controller 30 shown in FIGS. 4A to 4D.

Referring to FIG. 4A, the controller 30 is configured to interrupt the output current from the rectifier 54 to determine if the pipeline 100 is in a passive state. This interruption is periodic and performed after a certain number of cycles of monitoring of the probe. Accordingly, a counter for probe monitoring is set to 0 at the beginning of the cycle (step 1000) and its increased (1006) every time the probe makes a measurement (1002) for determining if the pipeline 100 is in a condition of corrosion or overprotection. Accordingly, when the controller determines that the number of cycles for periodic interruption has not been reached (at step 1004), it proceeds to measure the corrosion rate first.

If the corrosion rate is more than 0.1 mm/year (1008), the controller 30 calculates a new value for the current setpoint (i.e. output current from the rectifier 54, step 1010). The new value is calculated as the sum of old current and product of the anodic current and the proportional constant Kpa. Then the controller determines if this new current value is greater than the license limit of the rectifier (i.e. the maximum output current from the rectifier, 1012). If so, the controller 30 reassigns the new value for current set point to the rectifier license limit (1014) (see last step in FIG. 4A) so as to ensure operational safety. If the controller determines that the new current value calculated is less than the rectifier license limit or if the controller has reassigned the new value to the maximum current output, it attempts to determine if there are any cathodic currents above the overprotection threshold (i.e.

threshold beyond which undesirable reactions occur, 1016, see FIG. 4B). If it determines that the cathodic currents are within the limit, the controller 30 applies the new current value to the pipeline to counter the anodic currents observed at the probe 40 (1020, FIG. 4B). If the controller 30 detects that there are cathodic currents above the overprotection threshold, then it proceeds to take a set of actions to reduce the current to the structure (1022-1026).

If the corrosion rate determined is less than 0.1 mm/year, the controller 30 directly proceed to evaluate if there are any cathodic currents above the overprotection threshold (1028). If it finds there are no cathodic currents, it leaves the new value for current setpoint unchanged (i.e. new value of current set point=old value of current set point, 1032, see FIG. 4C) and proceeds to restart the cycle of probe monitoring again (i.e. goes back to step 1002). If the controller 30 detects that there are cathodic currents above the threshold, then it calculates a new current set point value as the sum of the old current set point value and a product of the excess cathodic current above the threshold and proportional constant of the controller (1030) (FIG. 4B).

When the counter for monitoring the probe has reached the number of cycles after which a determination for passivation is due, the controller 30 interrupts the output current from the rectifier 54 and makes a determination on the passivation state (2002, FIG. 4D). As described above, the controller looks at both the anodic and cathodic currents to determine if they are within the predetermined criteria. If the controller 30 detects that this is indeed the case, it decreases current to the pipeline 100. The new current set point is calculated as the sum of the old current set point and a product of the bias current and proportional constant of the controller Kpc. [step 2006].

If the controller 30 detects that the system is not in a passive state, steps 2002 to 2016 occur.

In embodiments of the protection system, the controller 30, in implementing the control to selectively interrupt the output current, can receive signals from one probe, or from two or more probes. In cases where the environment conditions along the pipeline are not homogenous (i.e., are heterogenous), multiple probes may be needed. Where the controller 30 receives information from two or more probes, the signals from the two or more probes can be multiplexed and fed to the controller via one line, or fed to the controller and then multiplexed by the controller, to control the rectifier.

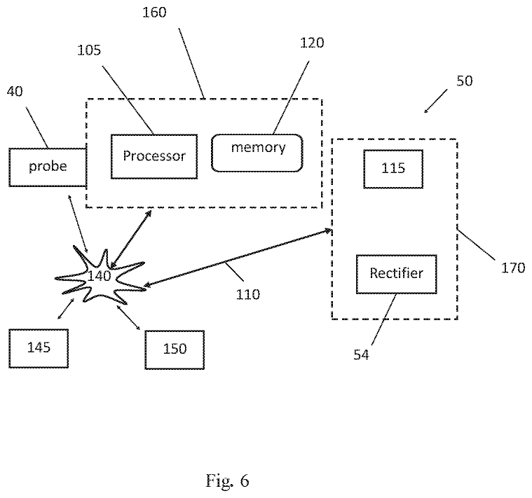

In an embodiment, the controller supplies control signal to a rectifier output control means. For instance, the rectifier output control means may be a switch at the output of the rectifier (or included in the rectifier circuit) which can be switched on and off via the control signals. In another example, the control signals can be provided to a variable resistor whose resistance is adjustable. These are examples only, and other means of adjusting and/or switching the output may be used. The rectifier output control means may be part of the rectifier circuit (e.g., see FIG. 5), or it may be provided separate to the rectifier circuit (e.g., see FIG. 6). It will be recognised that either implementation arrangement may be replaced with the other, in embodiments of the protection system.

FIG. 5 conceptually depicts a control arrangement. As depicted, the controller 30 may include a processing module 105 such as a microcontroller, CPU or an integrated circuit, to determine the control signals 110 for controlling the output of the cathodic protection system 50 (e.g., the output from the rectifier 54), on the basis of the data from the probe or probes.

Where applicable, the processing module may be adapted to execute algorithms to perform the required processing to determine the appropriate control signal. The algorithms may partially or wholly reside in a local memory 120 device collocated with processing module. The processing module 105 and memory 120 are shown as being collocated in a physical housing 130 but this is not a requirement of the invention. The processing module 105 and memory 120 are involved in generating the control signal, and thus are represented within the dashed lines. However, they may be collocated with the protection system 50.

In some embodiments, one or more of the algorithms, the parameters defining the local environmental conditions, control parameters such as overprotection time allowance, etc, are preloaded onto the local memory. However, in alternative embodiments, these can be can be configured at the time of setup. The local memory 120 may further be updatable. The update may be provided via a physical connection to the controller 30. Alternatively the memory may be updated via wireless connection 140, e.g., from a remote location via a long range connection (e.g., mobile data network such as 3G, 4G, 5G, or a wireless network such as WAN), or from a near location via a short range (e.g., Bluetooth®) or a near range (e.g., LORA). The wireless update may be provided from a remote computing device 145, such as a computer located at a monitoring location, or a mobile device 150. Control input defining the required parameters or other set values defining requirements to be met by the protection system, may also be provided via the remote computing device 145 or the mobile device 150.

The processing means may be collocated with means of adjusting or switching the rectifier output, such that the control signal is provided via a physical connection to control the operation of the switch, variable resistor, or other adjusting means.

In the depicted embodiment, the generation of the control signal is performed locally. Alternatively, the processing to generate the control signals, for controlling the operations of the rectifier output control means 115, may be remote from the rectifier 54. That is, the overall controller 30 is provided by both remote processing and a local actuator to control the rectifier output. An example is conceptually depicted in FIG. 6.

In FIG. 6, the control signal is provided over the wireless network 140. Here, the data from the probe or probes 40 are provided over the network 140 to the processing module 105. Control signals 110 generated by the processing module are then provided to the rectifier output control means 115. The rectangle 170 shown in dashed lines conceptually depicts that the rectifier output control means 115 and the rectifier 54 are part of the cathodic protection system 50.

It will be understood that where physical infrastructures allow, in further embodiments, a cabling connection may be used for data and/or control signal transmission. For example, the readings from the probe or probes 40 may be provided via the cabling to the processing module 105, which then generates the control signals accordingly, to be provided to the rectifier output control means 115.

Embodiments discussed with reference to FIG. 6, or equivalent embodiments, allow for a remote or aggregated control paradigm to be adopted. The processing module 105 and any local memory 120 may be provided at a server 160 which is responsible for controlling the outputs at a plurality of rectifiers for implementing the protection system for a pipeline or a network of pipelines at different locations.

For instance, local environmental conditions as measured by the probes connected to a pipeline or pipeline network may be provided to the server 160. The processing module or possibly multi-processing modules at the server location 160 determine the control signals accordingly, and then issue the control signals to the local rectifiers 54. In these embodiments, it will be appreciated that the probe data provided to the server will need include signals which identify the probe and/or the corresponding rectifier.

### EXAMPLES

Non-limiting examples will now be described, to further illustrate the advantageous properties of the CP control systems disclosed.

### Example 1

This example describes the experimental setup and conditions utilized for the proof-of-concept measurements for CP control system for a pipeline with a disbonded coating.

### Electrode Array

A 100 element X65 steel electrode array in a 25 by 4 arrangement was used. Electrodes were squares of 2.24 mm inside spaces 0.3 mm apart. The 3D printed cover used to simulate a disbonded coating was designed to generate a 1 mm crevice that covers 21 out of the 25 rows of electrodes. For all tests the electrode array was polished using 240 grit silicon carbide paper and running water as lubricant. Before the 3D printed cover was mounted onto the electrode array, a layer of the test soil was added over the electrodes. The intention behind this step is to ensure a continuous conductive path for the electrolyte within the crevice.

### Experimental Cell

A 2.5 L borosilicate electrochemical cell was used. The cell has a flange connection at one side where the electrode array was installed. The two graphite counter electrodes were used as anodes and potentials were measured against a Luggin capillary where the Ag/Sat. AgC/Sat. KCl reference electrode was installed. The test environments used where mixes of sand and 0.01 M Na₂SO₄ at fractions of the sand water holding capacity (all tests were performed at 22±2° C.).

### Instrumentation

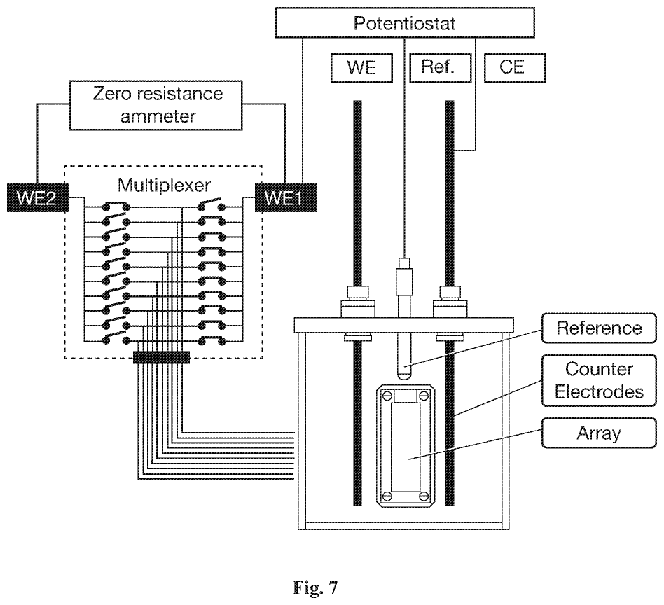

Referring now to FIG. 7, the instrumentation used for measuring the distribution of currents over the surface of the electrode array without interrupting the CP was as follows.

A multiplexer distributed the connections of the 100 electrodes in the array, maintaining 99 of them connected to the WE1 output terminal and the remaining electrode connected to the WE2 output terminal. In order to measure the current flowing throughout the electrode connected to WE2, a zero resistance ammeter (was interposed between WE1 and WE2. In addition to measuring currents, the ZRA kept WE1 and WE2 (i.e. all the electrodes in the array) at the same potential. The CP supplied to the array was managed by a Bio logic VMP3 potentiostat in a three electrode configuration, where WE1 acted as the working electrode. The current flowing throughout each electrode of the array was registered by swapping the electrode connected to WE2, following a predetermined sequence that swept the whole array. A make before break switching sequence between successive electrodes was followed to avoid any momentary disconnection of CP. Current distributions were measured consecutively, with a 10 s pause in between measurements.

### Response of System to Anodic Perturbations Generated

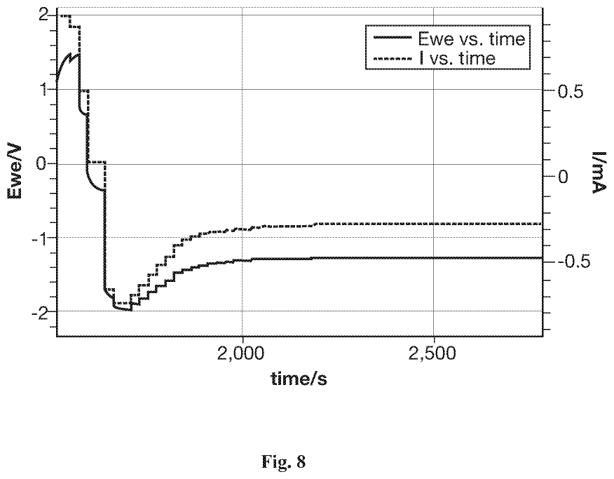

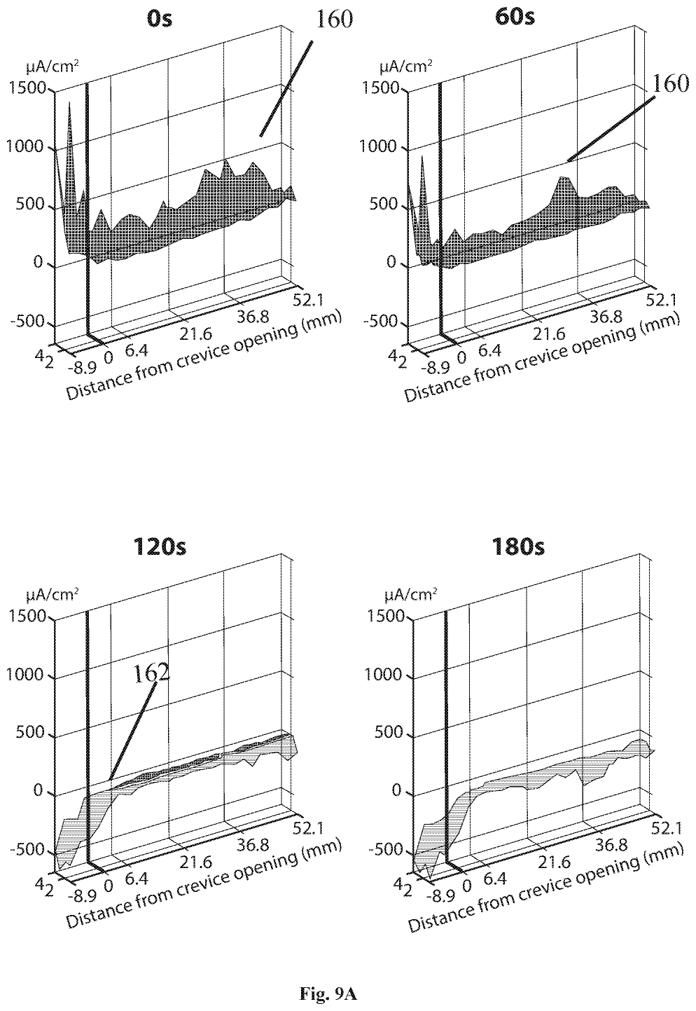

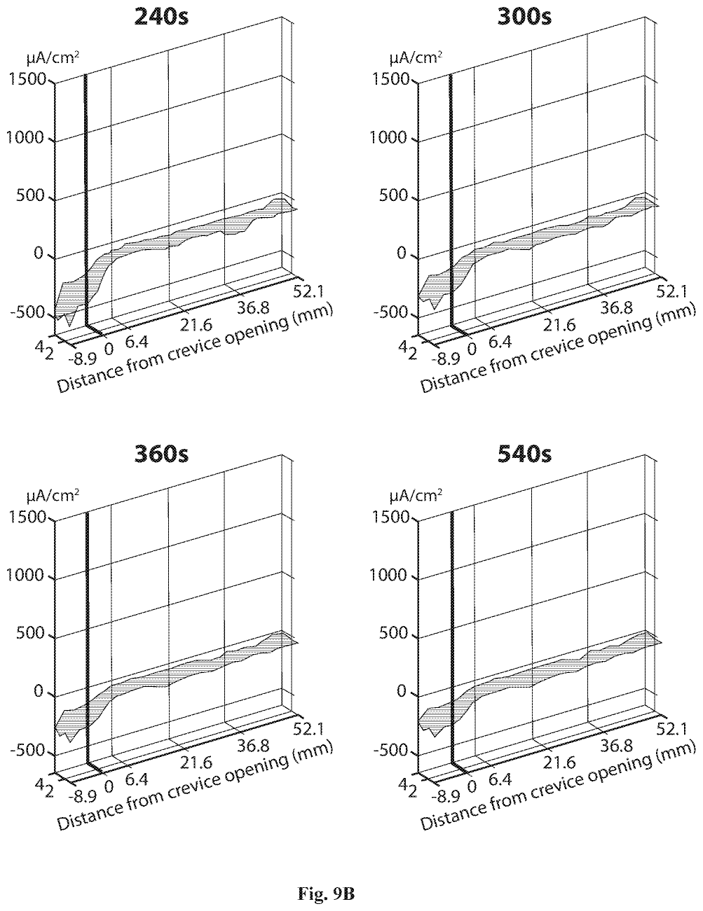

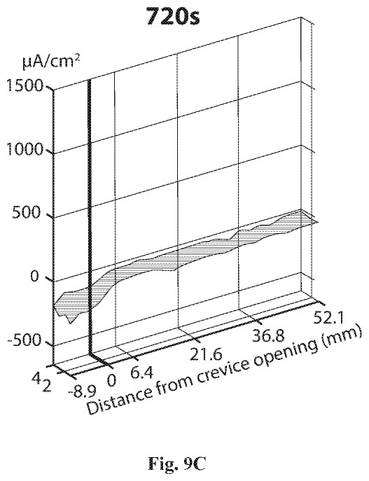

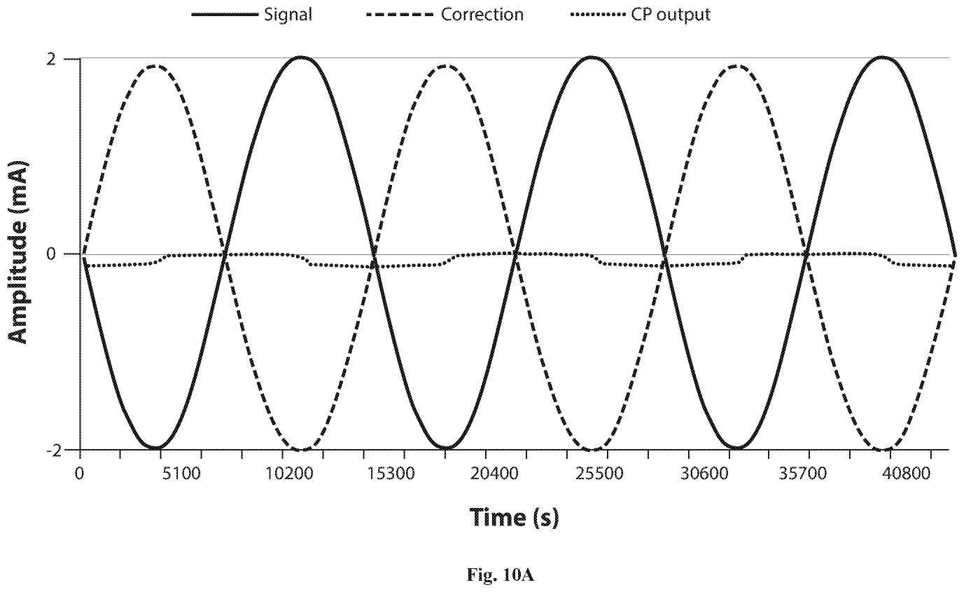

Referring now to FIGS. 8 and 9A to 9C, the response of the CP system to anodic perturbations will be described. 30% WHC sand was employed for the tests. A random anodic perturbation was generated during a steady state operation of the CP system and the response of the CP system was monitored. In this case, the initial anodic perturbation was large and some overshooting (as shown in the graph of FIG. 8) is observed before a stable CP current output was achieved. The stable CP current output found produced an IR drop free potential of about −1.27 V vs. Ag/AgCl (−1.39 V CSE) which is in the overprotection range. This suggests that the current threshold that was arbitrarily selected should be lower for this environment.

FIGS. 9A to 9C presents the evolution of the current density maps measured by the electrode array over the same perturbation cycle. Due to the overshooting, it took 15 cycles (300s) to mitigate most of the anodic activity (160 shown in FIG. 9A) and overprotection (162 shown in FIG. 9A). The data reveals that the system is able to detect and respond to anodic perturbations.

### Response of System Under Dynamic Conditions

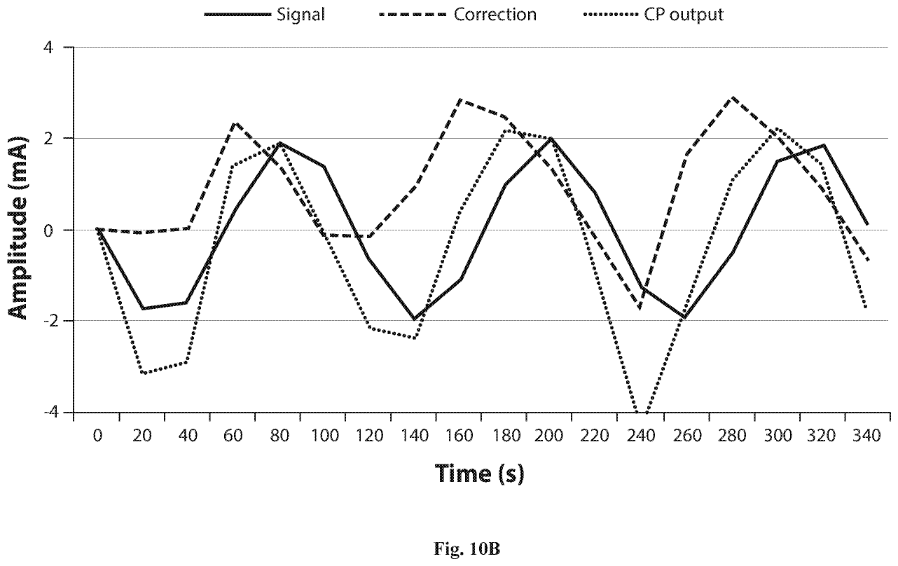

The performance of the proof-of-concept system under dynamic conditions will now be described. FIGS. 10A and 10B illustrate the typical results obtained at the two ends of the frequency spectrum. At the low frequency end of the spectrum, the correction introduced by the controller is almost a mirror image of the test signal. As a result, the CP current output remained almost constant. FIG. 10B presents the same type of result as FIG. 10A, but for the first unstable frequency tested. At this higher frequency the number of data points collected per cycle was only 6, resulting in sharper and noisier curves. The delay produced by the 20 s required for data acquisition, induces a more important phase shift between the signal and correction curves at this frequency. The results show that the controller is able to detect and respond to changes occurring at a lower frequency of the spectrum much better than changes occurring at higher frequencies.

### Example 2

This example describes the set up utilized to evaluate the comparative performance of closed loop potential control with conventional control.

### Experimental Arrangement

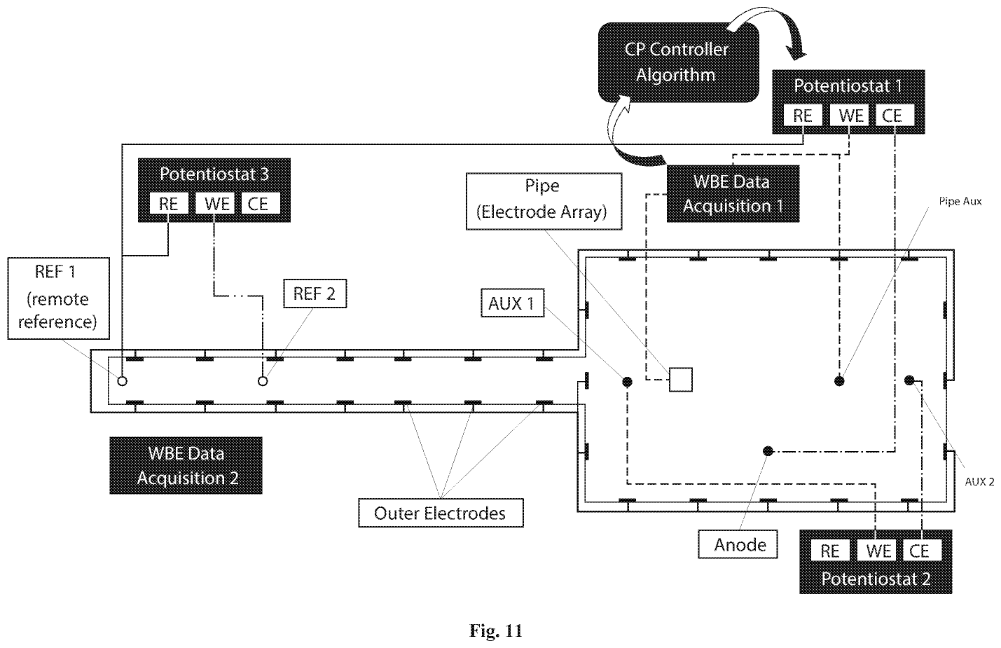

The experimental arrangement used for these comparative tests is illustrated in FIG. 11. The simulation of an infinite media is achieved by 50 outer Titanium electrodes (Outer electrodes in FIG. 11 that are maintained at the same electrical potential between them). When exposed to an uneven soil potential across the box, small currents flow among these electrodes, similarly to the current that would flow across the soil outside the box volume if this were a true infinite media. These small currents were constantly monitored throughout the tests (WBE data acquisition unit 2 in FIG. 11). A reference electrode (REF 1 in FIG. 11) was placed at the end of the elongated part of the box. This is the remote electrode used as a remote reference for all potential measurements, even those controlling the CP unit when in autopotential mode. The remoteness of the reference electrode was confirmed by measuring vanishingly small currents on the Titanium outer electrodes and by constantly monitoring potential differences lower than 20 mV (potentiostat 3 in FIG. 11) between this reference electrode and another identical electrode (REF 2 in FIG. 11) located 20 cm away.

At the main section of the box, the pipeline was simulated using an electrode array (pipe electrode array in FIG. 11) and an auxiliary Ti electrode (pipe aux in FIG. 11). In order to induce stray currents on the simulated pipeline, a current was imposed (potentiostat 2 in FIG. 11) between two additional Ti electrodes (Aux 1 and 2 in FIG. 11). On this setup, a potentiostat (potentiostat 1 in FIG. 11 represents the CP rectifier and controls the current supplied to the anode (Anode in FIG. 11) When evaluating the conventional potentiostatic closed loop control, a potential equivalent to 850 mV vs. CSE was maintained between REF 1 and the pipe. When evaluating the new closed control method based on measurements of the electrode array, the data collected by the WBE data acquisition unit 1 was fed to a controller program that constantly recalculated the CP current to apply.

For these tests, no cover aiming to simulate a disbonded coating was placed over the electrode array. The current flowing between the auxiliary electrodes was varied in 90 min steps of 1 mA from 5 mA to 10 mA.

Before the experimental setup was constructed, the basic geometry and expected current distribution of the electrochemical cell were studied using a finite elements model. The governing equation for the model is the two dimensional form of Ohm's law. The model was limited to 2D because experimental conditions were maintained constant across the height of the electrochemical cell.

The boundary conditions selected for the anode, the electrodes simulating the pipe and the auxiliary electrodes used to inject the stray current into the system, were constant. The current flowing between the auxiliary electrodes was 25 mA. The electrodes simulating the pipe were at a potential of 1.5 V and the anode was at a potential of 2 V. The media conductivity was 0.01 S/m. In addition, when the Ti outer electrodes were part of the model, they were constrained at a potential of 0 V.

### Results

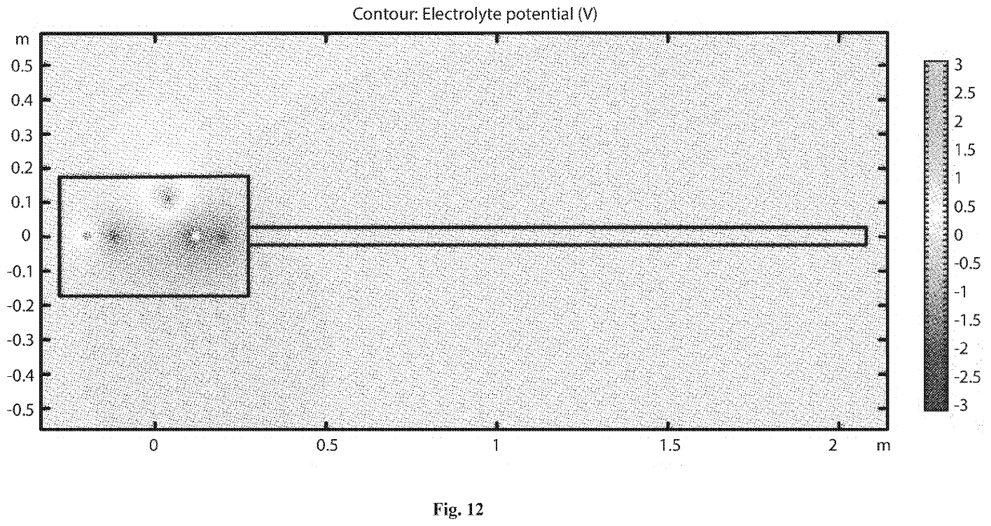

FIG. 12 presents the potential distribution results for an infinite media. Here the geometry of the experimental arrangement box is included only for reference and does not contribute to the model. As expected, the potentials around the anode and the auxiliary electrode acting as the source of stray current show positive values, while the electrodes simulating the pipe and the auxiliary electrode acting as a sink for the stray current present negative values. More importantly, a gradient is produced over the elongated part of the box where potentials remain nearly constant at zero at the far end, indicating that this would be a suitable location for a remote reference electrode.

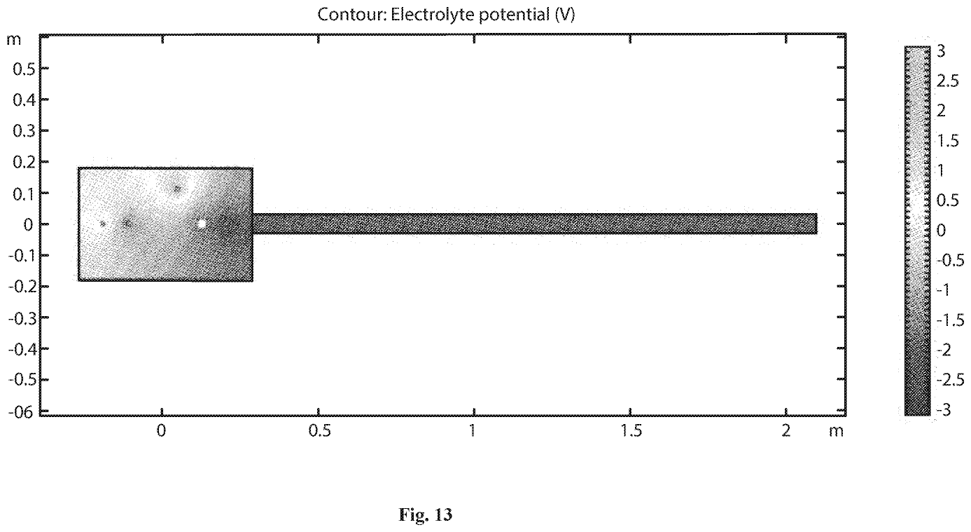

FIG. 13 presents the simulated potential distribution for a scenario where the conductive media is limited to only the inside of the box and no outer Ti electrodes are used. The boundary conditions for the box walls constrain the current flow to zero. In this case, the potentials along the elongated part of the box remain constant at a value similar to that present near the auxiliary electrode acting as a sink for the stray current. In other words, the elongated part of the box is acting as a Luggin capillary. Consequently, the far end of the elongated part of the box would not be a suitable location for a remote reference electrode in this case because the potential of the electrolyte at this location depends on the magnitude of the stray currents injected to the system.

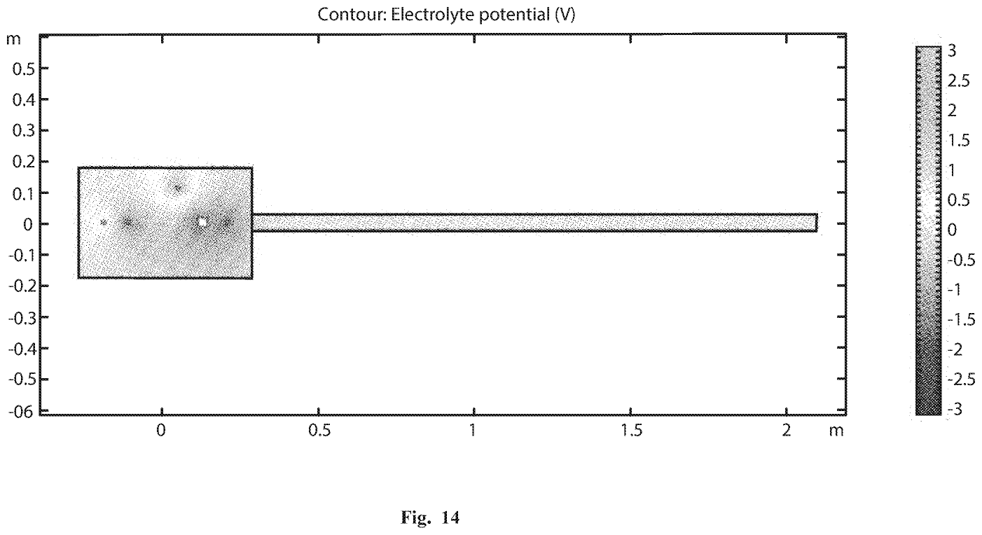

FIG. 14 presents the potential distribution results for the finite element simulation for the case where the media is limited to the inside of the box and the Ti outer electrodes are electrically connected among them. In this condition, the potential distribution inside the box is similar to that found for an infinite media and a potential gradient is also produced along the elongated part of the box.

Thus, as a conclusion of the simulations, it is expected that the use of outer electrodes would produce a region at the far end of the elongated part of the box where potential is nearly constant and independent of the stray current applied.

### Validation

This example illustrates the results of validation of the set up proposed in Example 2 for comparative testing.

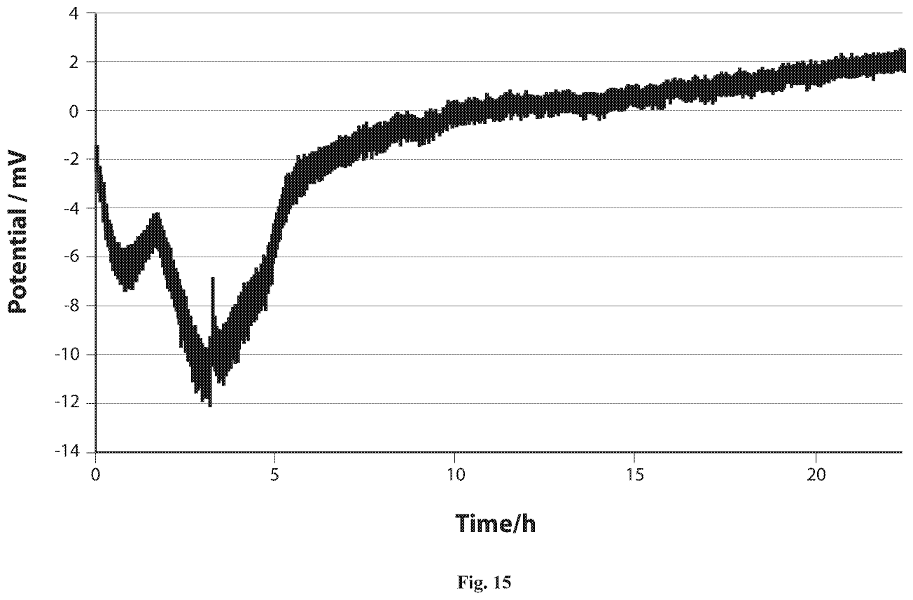

FIG. 15 presents the difference between REF 1 and REF 2 (according to the labels in FIG. 11) for the whole range of stray currents applied. The difference never exceeded 20 mV, which is considered the typical variation among reference electrodes of the same type.

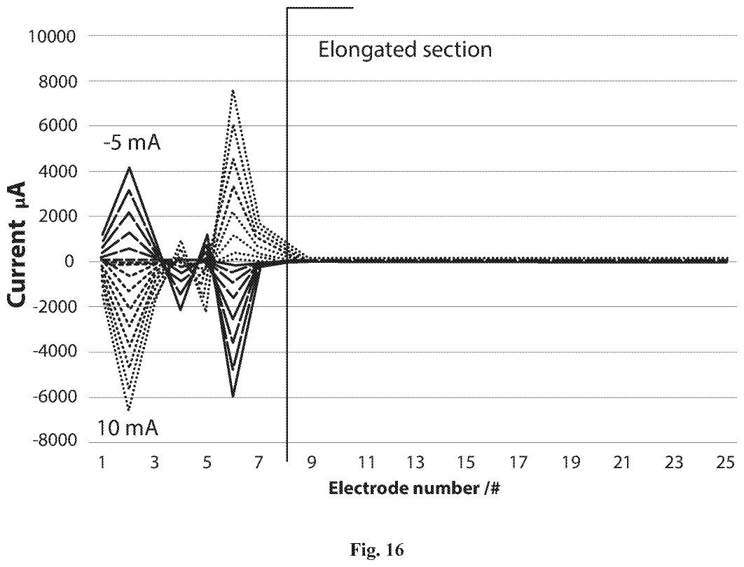

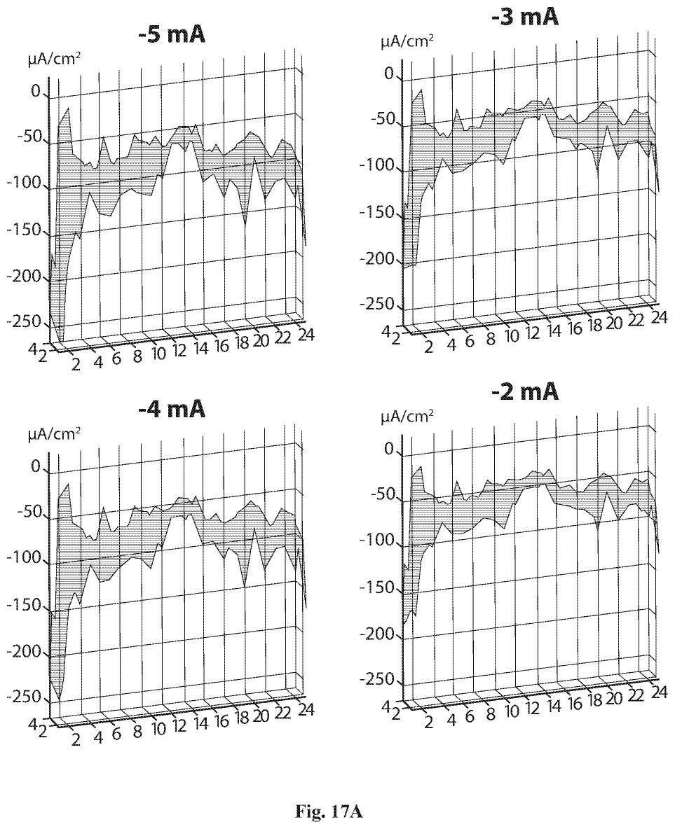

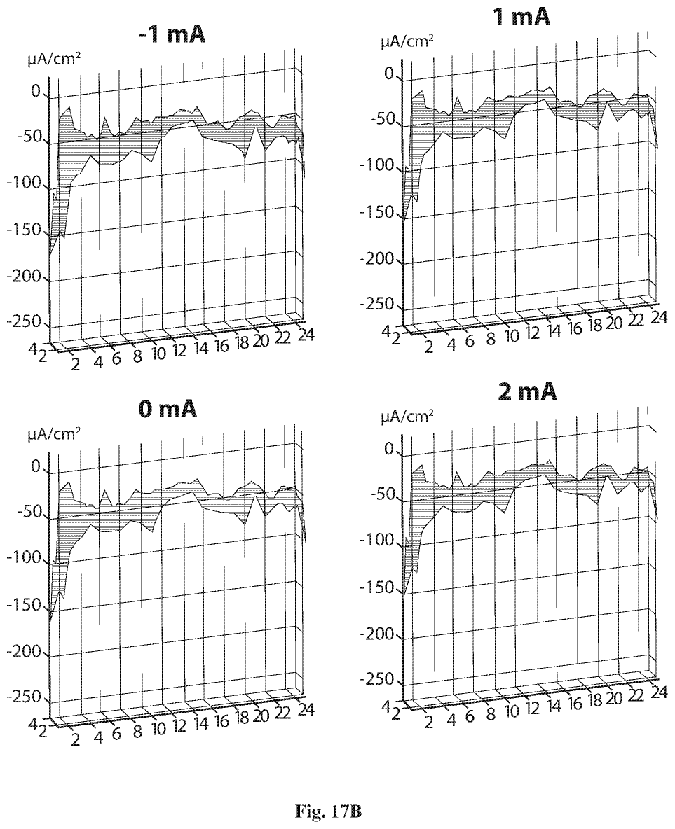

FIG. 16 presents the current flowing through the Ti outer electrodes for all applied stray current values while the controller was in autopotential mode. This information further proves the validity of the remote reference electrode presenting a gradient from electrode 8 onwards which rapidly falls to near zero currents.

### Example 3

The Example describes the comparative performance of autopotential control technique with the proposed closed loop control technique. The testing was performed in an environment comprising sand with 0.1 M Na₂SO₄ solution at 60% WHC.

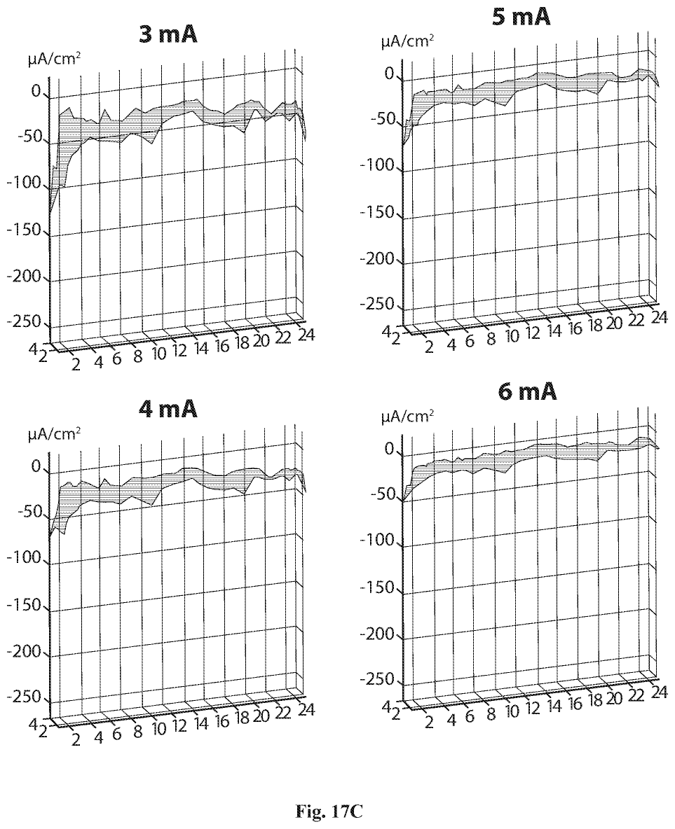

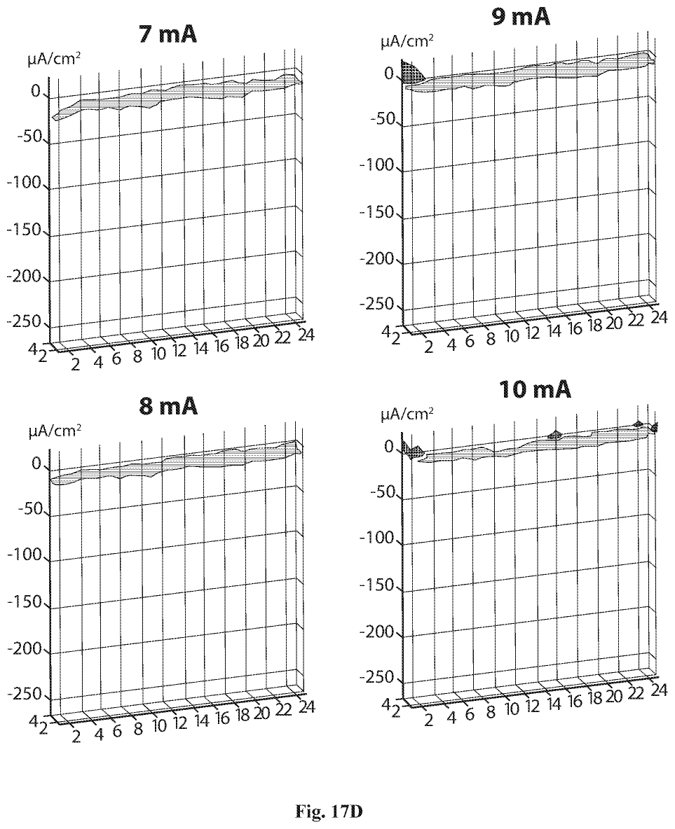

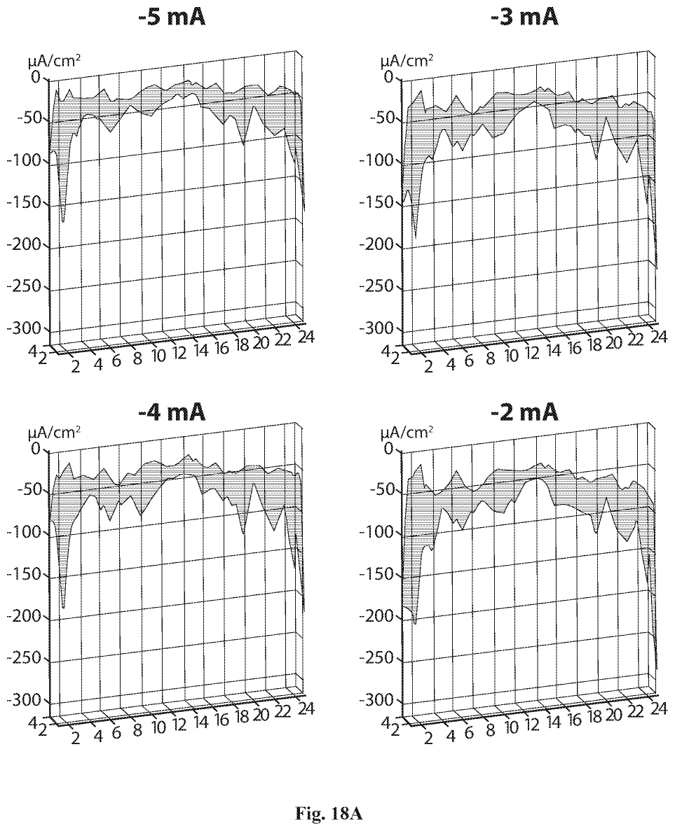

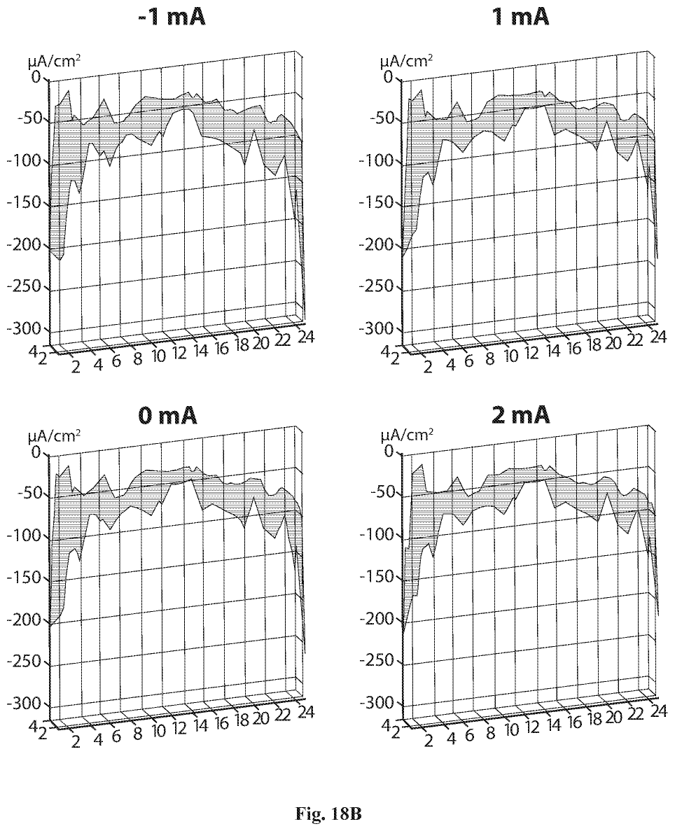

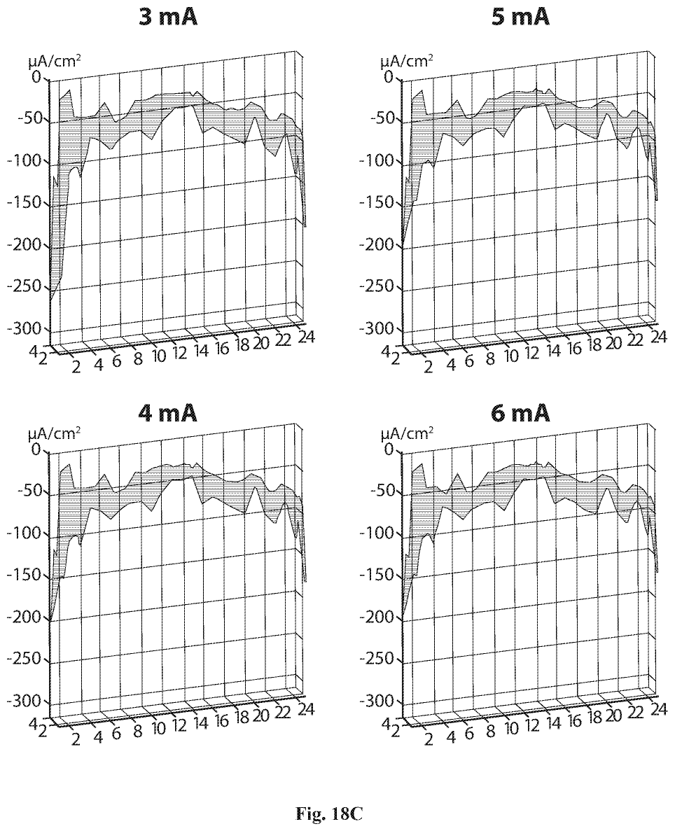

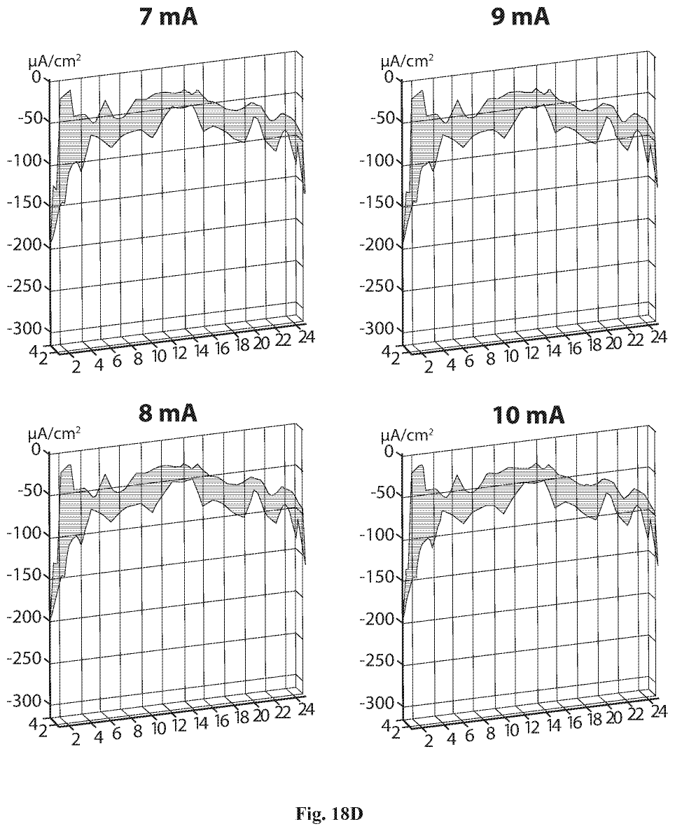

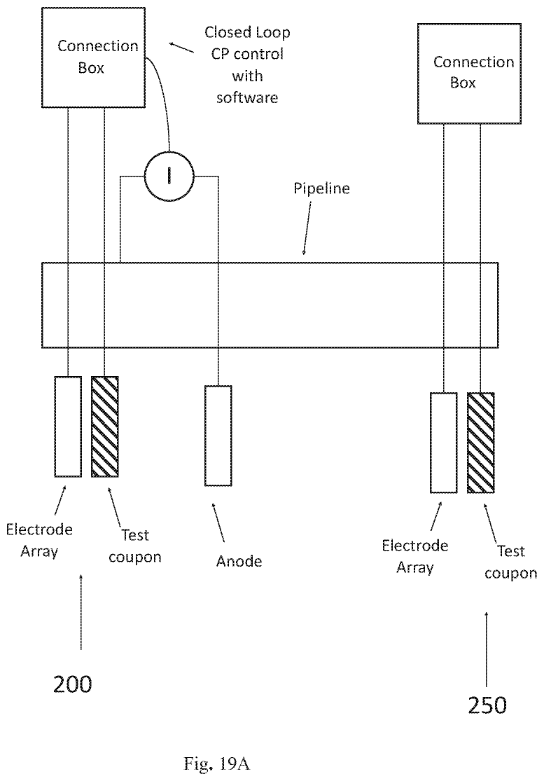

Referring to FIGS. 17A to 17D and 18A to 18D, the autopotential control produced different current density maps when different levels of stray current were applied. Current density maps presented larger cathodic currents when cathodic stray currents were applied and anodic current densities when anodic stray current densities were applied. In contrast, when the new closed control loop was used, no obvious changes in the current density maps are observed despite the effect of changing stray currents.

Potentials against the remote reference electrode ranged from 580 mV CSE to 1510 mV CSE when using the new control loop to compensate for the stray currents.

### Example 4

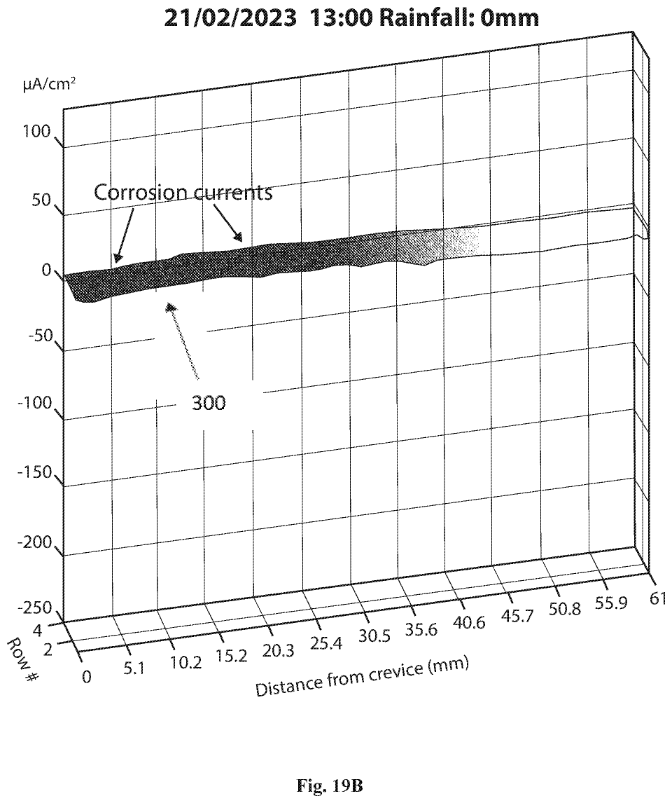

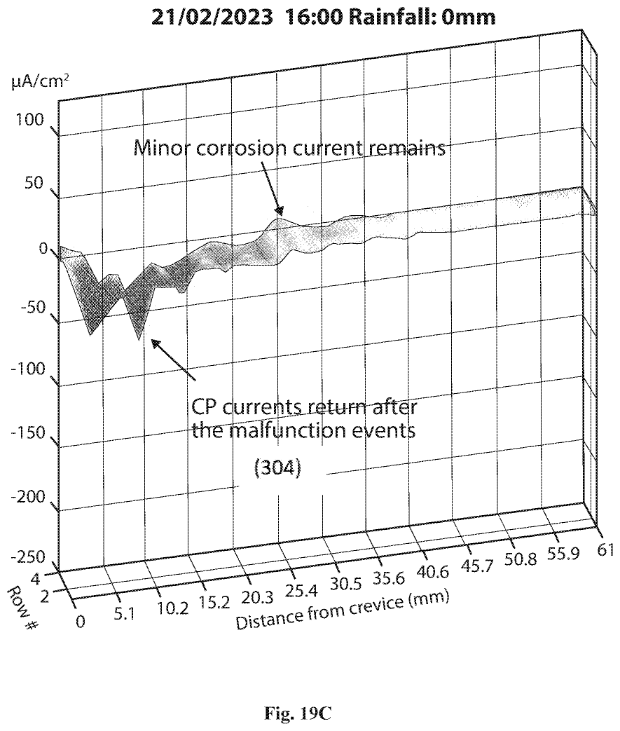

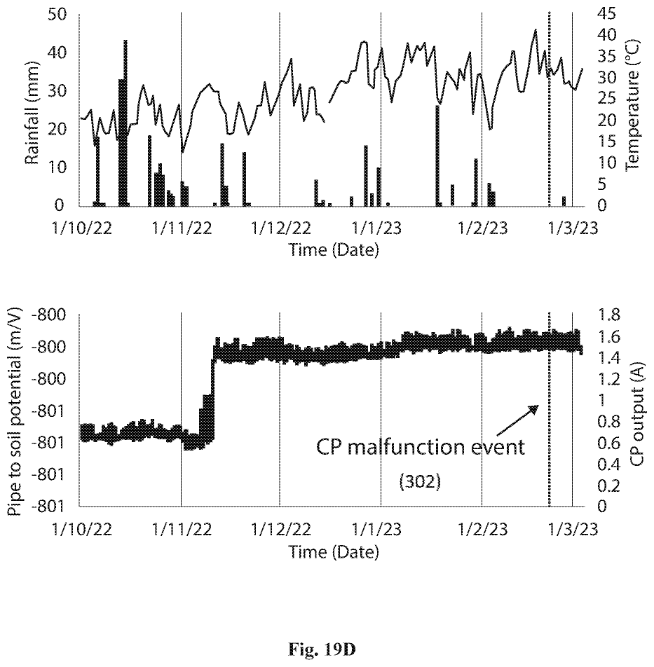

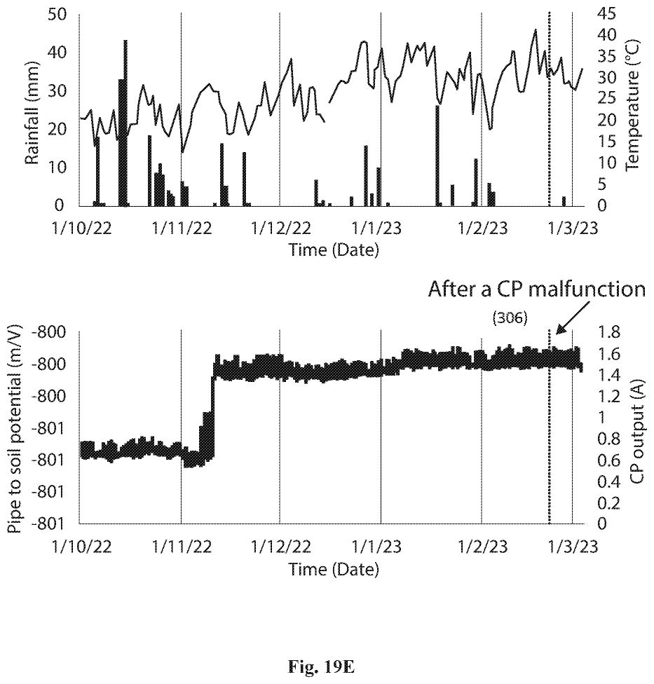

This example illustrates the capability of the proposed closed loop system to detect any malfunctions associated with the Closed loop corrosion protection system and method. The system was implemented on the field and a schematic of this system is shown in FIG. 19A. The system was installed on a pipeline running between two locations namely Kialla (200) and Euroa (250) in Victoria. The two locations were approximately 20 km apart. At the Kialla site (200), the probe was installed together with CP protection (i.e. the probe was under CP protection). At the Euroa site (250), the probe was installed without the closed loop corrosion protection system (i.e. just the probe and test coupons were installed by electrically connecting to the pipeline). The field installation also included conductivity, humidity and temperature sensors, wireless system to transmit data to and from the controller, retrievable coupons, anodes, solar panels and rechargeable batteries, a reference electrode, mechanical interfaces between the rectifier and the controller. The probes and sensors are buried at the same depth and close vicinity of the pipeline and are connected electrically to the pipeline.

The probe installed on the field at Kialla site detected a major corrosion occurring on the probe from 21 Feb. 2023, as shown in FIG. 19B. This major corrosion event (indicated as 300 in FIG. 19B) lasted for approximately 6 hours. A review of the CP potential recordings identified a CP ‘malfunction’ event (302) (see FIG. 19D), possibly due to CP shutdown, external electrical interferences or some other reasons. This result suggests that the corrosion probe and monitoring system quickly and accurately detected the occurrence of corrosion when there was a CP malfunction event. After the CP returned to normal (see FIG. 19E), corrosion currents disappeared (see FIG. 19C) and CP currents return (304, 306) after the CP ‘malfunction’ event.

### Example 5

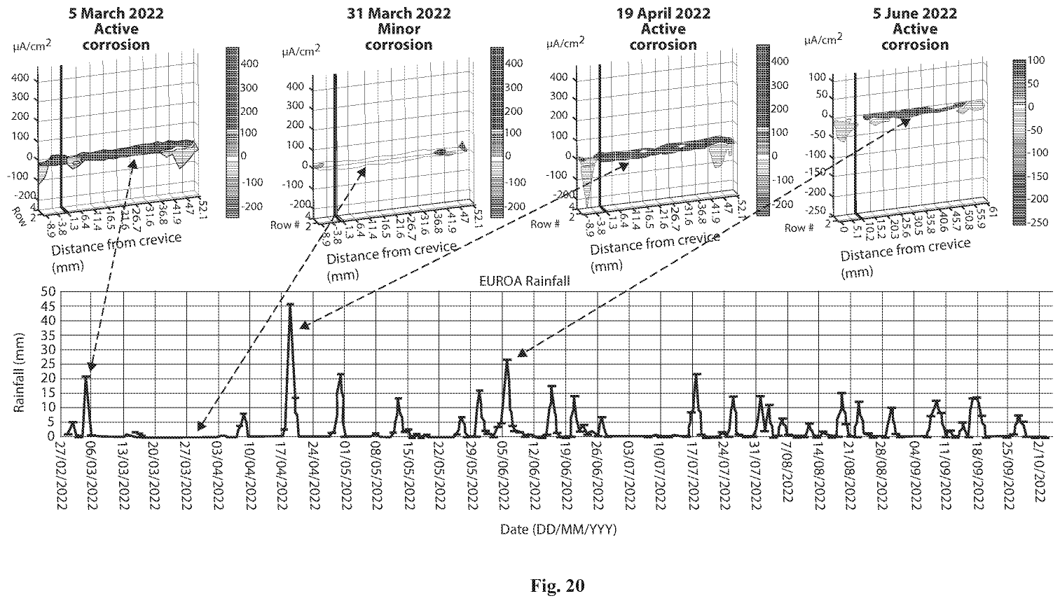

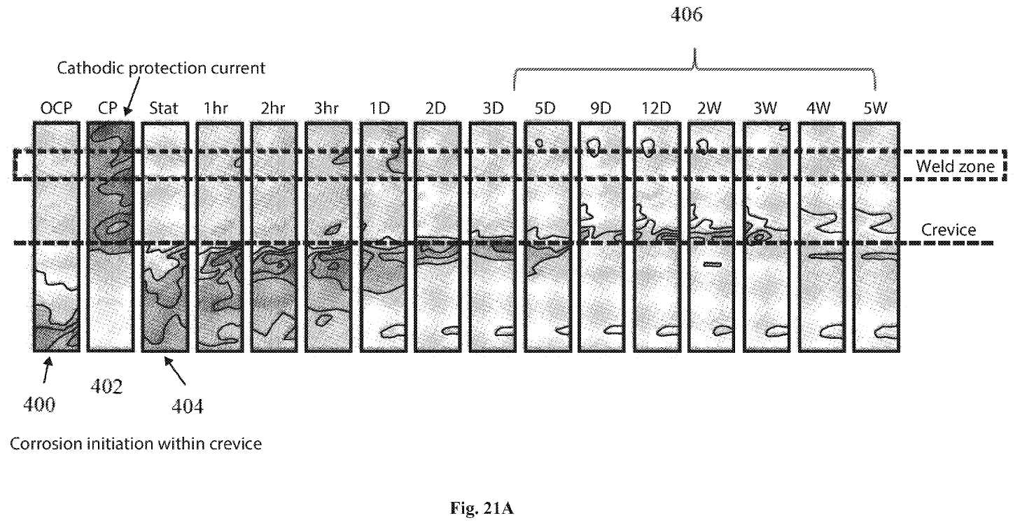

This example describes how the closed loop system may be utilized to detect changes in corrosion behaviour due to changes in rainfall. As shown in FIG. 20, major corrosion (indicated by the positive currents observed in the corrosion current maps) occurred during periods of major rainfall (e.g. on 5 Mar. 2022 and 19 April 2022). These data show a clear correlation between rainfall and corrosion that was observed over March-June period.

These results are in agreement with our findings from previous laboratory testing in sandboxes that most active corrosion under disbonded coatings (CUDC) often occur to a CP protected buried pipeline over wet-dry seasonal change periods. Application of more CP on the pipeline section through the CPU (CP capacity check) to the system has led to more cathodic current, suggesting the corrosion probe was responding correctly to pipeline CP levels. These results confirms that the corrosion probe and instrumentation system worked correctly and corrosion could be reduced by applying extra CP current.

### Example 6

This example describes how the system and method of the present invention can be used for monitoring and controlling marine corrosion.

The probe 40 described in the above examples can be utilized with a few differences in the construction. The region of the probe 40 that is outside the crevice now comprises electrodes that have a composition that is the similar to that of the weld zone of a pipeline. This can be prepared by cutting a section of the welded pipe region and using the material to prepare the electrodes that are then used in the array. Once fabricated, the probe can be immersed into sea water next to the pipeline. All the connections to the control system and rectifiers can be similar to that used for buried pipelines.

The probe was designed and used to simulate and monitor the presence of three types of critical corrosion that can occur on marine steel structures, i.e. pitting corrosion at welds along spools (i.e. individual segments of pipe), crevice corrosion at bolts on flanges between spools, and crevice corrosion between flanges bolted together. The electrode array probe consisted of one hundred 1.6 mm diameter pipeline steel wires arranged in a 4 by 25 square array. The wires were mounted in epoxy resin and equally spaced at a distance of approximately 0.27 mm. The electrode array probes were used for continuous field in-situ electrochemical monitoring, to obtain information about the initiation, propagation and mechanism of localised forms of metal corrosion, under simulated oil and gas infrastructure conditions. The field corrosion monitoring tests were conducted by exposing corrosion probes in the ocean of Queenscliff, Victoria field test site.

FIG. 21A shows that at the very beginning of the exposure of the probe to ocean seawater, corrosion initiation started within the crevice area, as indicated by higher corrosion rates in the maps (400). In order to simulate and evaluate the effect of cathodic protection on marine structures, a cathodic protection potential of −900 mV vs Cu/CuSO₄ reference electrode was applied to the probe for a short period of time (approximately 2 hours). Under cathodic potential, corrosion in the crevice area reduced to almost zero (402) with all the electrodes in the electrode array showing negative cathodic currents, as indicated by the low corrosion rates (402) in FIG. 21A. After the cathodic protection was switched off, active corrosion recommenced inside the crevice and reached up to 7 mm/y within about half an hour (404). Within a few days (406), the crevice corrosion moved outwards, that is, towards the crevice mouth. Most corrosion initiated and propagated around the crevice and its mouth areas, as shown in enlarged maps in FIG. 21B. These observations are in agreement with industry experience that the greatest degree of crevice corrosion tends to occur at locations such as on flanges between spools, between flanges bolted together, and at end plates on parked pipelines in ocean. This also confirms that CP is able to count against corrosion on offshore structures. The measurements are in good agreement with actual corrosion that occurred on the probe surface after 61 weeks of ocean testing.

In the claims which follow and in the preceding description of the invention, except where the context requires otherwise due to express language or necessary implication, the word “comprise” or variations such as “comprises” or “comprising” is used in an inclusive sense, i.e. to specify the presence of the stated features but not to preclude the presence or addition of further features in various embodiments of the invention.

1. A method of controlling corrosion in a metallic structure subjected to cathodic protection, comprising:
providing a probe that is capable of simulating at least one condition of a metallic structure subjected to cathodic protection;
measuring at least one characteristic at the probe indicative of one or more states of the probe; and
controlling at least one parameter of the cathodic protection subjected applied to the metallic structure in response to the at least one measured characteristic.

2. The method according to claim 1, further comprising;
associating the probe and the metallic structure with one another so that they are maintained at an identical electrical potential whereby corrosion and cathodic protection at the metallic structure also occurs at the probe.

3. (canceled)

4. The method according to claim 1, wherein at least one of the one or more states of the probe is a rate of corrosion at the probe.

5. The method according to claim 4, wherein the at least one measured characteristic is an anodic current at the probe.

6. The method according to claim 4, further comprising:
increasing the cathodic protection subjected to the metallic structure when the at least one measured characteristic indicative of the rate of corrosion at the probe and/or a pattern of corrosion at the probe is outside a predetermined criteria.

7. The method according to claim 1, wherein the probe is subject to cathodic protection and at least one of the one or more states of the probe is a state of overprotection of the probe by the cathodic protection.

8. The method according to claim 7, wherein the at least one measured characteristic is cathodic current at the probe.

9. The method according to claim 7, further comprising:
reducing the cathodic protection subjected to the metallic structure when the at least one measured characteristic is indicative of the state of overprotection of the probe is outside a predetermined criteria.

10. The method according to claim 1, wherein at least one of the one or more states of the probe is a passivated state.

11. The method according to claim 1, wherein the at least one measured characteristic is both an anodic current and a cathodic current at the probe.

12. The method according to claim 10, wherein a passivated state is indicated by significant decrease in corrosion rates.

13. The method according to claim 10, further comprising:
reducing and/or removing the cathodic protection subjected to the metallic structure when the at least one measured characteristic indicative of a passivated state of the probe is within a predetermined criteria.

14. (canceled)

15. (canceled)

16. (canceled)

17. The method according to claim 1, wherein the probe is exposed to identical or substantially similar environmental conditions as the metallic structure; and/or
wherein the at least one condition is a localized condition of the metallic structure, wherein the localized condition is a defect of the metallic structure or stray currents interacting with the metallic structure.

18. (canceled)

19. (canceled)

20. The method according to claim 17,
wherein the metallic structure comprises a coating;
wherein the defect is a disbonded coating formed on the coating of the metallic structure; and
wherein the localized condition is corrosion under the disbonded coating.

21. (canceled)

22. The method according to claim 1, wherein the probe comprises an array of electrodes and the measuring the at least one characteristic at the probe comprises measuring the at least one characteristic at a plurality of the array of electrodes to form a distribution map of the at least one measured characteristic across the array of electrodes.

23. The method according to claim 22, wherein the at least one parameter is controlled in response to the distribution map of the at least one measured characteristic across the array of electrodes.

24. The method according to claim 1, wherein the metallic structure is a pipeline buried in soil or a structure submerged in a marine environment.

25. (canceled)

26. (canceled)

27. A control system for controlling a corrosion protection system for a metallic structure; comprising
a controller for controlling at least one parameter of a corrosion protection system for a metallic structure; and
a probe capable of simulating at least one condition of the metallic structure;
wherein the controller is adapted to receive a data from the probe, the data being indicative of one or more states of the probe, and determine a control signal for controlling the at least one parameter of the corrosion protection system on the basis of the data from the probe.

28. (canceled)

29. (canceled)

30. (canceled)

31. (canceled)

32. (canceled)

33. (canceled)

34. (canceled)

35. (canceled)

36. (canceled)

37. (canceled)

38. (canceled)

39. (canceled)

40. A cathodic corrosion protection system applied to an apparatus for monitoring and controlling corrosion in a metallic structure, the apparatus comprising:
a probe configured to simulate at least one corrosion condition of a metallic structure and configured to measure a characteristic indicative of one or more states of the probe; and
a controller coupled to the cathodic corrosion protection system and the probe, wherein the controller controls at least one parameter of cathodic protection subjected to the metallic structure in response to the measured characteristic.

41. (canceled)

42. The control system according to claim 27, wherein the control system is adapted to receive control input comprising one or more of a protective current threshold and an overprotection time allowance.
